(19) United States
(12) Patent Application Publication
(10) Pub. No.: US 2024/0162679 A1
(43) Pub. Date: May 16, 2024

(54) LIGHT EMISSION DEVICE AND LIGHT SOURCE DEVICE

(71) Applicant: HAMAMATSU PHOTONICS K.K., Hamamatsu-shi, Shizuoka (JP)

(72) Inventors: Kazuyoshi HIROSE, Hamamatsu-shi, Shizuoka (JP); Koyo WATANABE, Hamamatsu-shi, Shizuoka (JP); Hiroki KAMEI, Hamamatsu-shi, Shizuoka (JP)

(73) Assignee: HAMAMATSU PHOTONICS K.K., Hamamatsu-shi, Shizuoka (JP)

(21) Appl. No.: 18/283,894

(22) PCT Filed: Mar. 2, 2022
(86) PCT No.: PCT/JP2022/008935

§ 371 Date: Sep. 25, 2023

(30) Foreign Application Priority Data
Mar. 30, 2021 (JP) 2021-058203

(51) Int. Cl. H01S 5/026; G02B 5/32

(52) U.S. Cl. CPC H01S 5/026; G02B 5/32

(57) ABSTRACT

A light-emitting device is an S-iPM laser of M-point oscillation including a phase modulation layer. Four-direction in-plane wavenumber vectors each including a wavenumber spread corresponding to an angular spread of light output from the light-emitting device are formed on a reciprocal lattice space of the phase modulation layer. The magnitude of at least one of the in-plane wavenumber vectors is smaller than 2π/λ. A predetermined phase distribution included in the phase modulation layer includes an element for focusing the light output.

### TECHNICAL FIELD

The present disclosure relates to a light-emitting device and a light source device.

### BACKGROUND ART

Patent Literature 1 discloses a technology for removing zero-order light contained in an output of an S-iPM (Static-integrable Phase Modulating) laser. A light-emitting element disclosed in this literature includes an active layer and a phase modulation layer. The phase modulation layer includes a base region and a plurality of modified refractive index regions. The plurality of modified refractive index regions has a refractive index different from a refractive index of the base region, and is distributed in a two-dimensional form on a surface perpendicular to the thickness direction of the phase modulation layer. When a virtual square lattice is set on the surface, the center of gravity of each modified refractive index region is arranged away from the corresponding lattice point and has a rotation angle around the lattice point in consonance with the phase distribution according to an optical image. A lattice spacing of the square lattice and a light emission wavelength of the active layer satisfy a condition for M-point oscillation. On a reciprocal lattice space of the phase modulation layer, four-direction in-plane wavenumber vectors each include a wavenumber spread corresponding to an angular spread of an optical image. The magnitude of at least one of the four-direction in-plane wavenumber vectors is smaller than 2π/λ.

Patent Literature 2 discloses a control device of a spatial light modulator. This control device includes a lens, the spatial light modulator, an image capturing device, a calculation unit, an analysis unit, and a change unit. The spatial light modulator has a modulation surface on which a plurality of modulation pixels is two-dimensionally arranged. The spatial light modulator presents a first modulation pattern on a modulation surface and outputs a first modulated light to form a first light spot and a second light spot on a pupil plane of the lens. The image capturing device has an image capturing surface on which a plurality of photoelectric conversion pixels is two-dimensionally arranged. The image capturing device captures a first striped pattern image formed on a focal plane of the lens by the first modulated light with the image capturing surface. The image capturing device generates first image data representing the light intensity distribution of the first striped pattern image. The calculation unit calculates at least one type of first parameter among intensity amplitude, phase shift amount, and intensity average based on the first image data. The analysis unit obtains deviation of the relative position of reference coordinates of the modulation surface from the optical axis of the lens based on the first parameter. The change unit changes the origin position of the reference coordinates on the modulation surface to reduce the deviation of the relative position.

### CITATION LIST

### Patent Literature

Patent Literature 1: WO No. 2020/45453
Patent Literature 2: Japanese Unexamined Patent Publication No. 2016-224412

### Non Patent Literature

Non Patent Literature 1: Y. Kurosaka et al., “Effects of non-lasing band in two-dimensional photonic-crystal lasers clarified using omnidirectional band structure”, Opt. Express 20, 21773-21783 (2012)

### SUMMARY OF INVENTION

### Technical Problem

Conventionally, optical components such as lenses have been used as an optical system for focusing light from a light source in a device including a light source. When miniaturization of such a light source device is required, the light source can be remarkably miniaturized by using, for example, a semiconductor light-emitting element. Meanwhile, it is difficult to miniaturize optical components for focusing light, which is a factor that hinders the miniaturization of the light source device.

An object of the present disclosure is to provide a light-emitting device capable of miniaturizing a light source device that outputs light while focusing the light, and a light source device including the light-emitting device.

### Solution to Problem

A light-emitting device according to the present disclosure includes a light emission portion and a phase modulation layer. The phase modulation layer is optically coupled to the light emission portion and includes a base region and a plurality of modified refractive index regions. The plurality of modified refractive index regions has a refractive index different from a refractive index of the base region, and is distributed in a two-dimensional form in a plane perpendicular to a thickness direction. A center of gravity of each of the modified refractive index regions has a first arrangement form or a second arrangement form. In the first arrangement form, the center of gravity of each of the modified refractive index regions is arranged away from a corresponding lattice point of a virtual square lattice set in the plane, and has an individual rotation angle around the lattice point according to a predetermined phase distribution. The rotation angles of the centers of gravity of at least two modified refractive index regions are different from each other. In the second arrangement form, the center of gravity of each of the modified refractive index regions is arranged on a straight line passing through the lattice point of the square lattice and inclined to the square lattice. An inclination angle of a plurality of the straight lines respectively corresponding to the plurality of modified refractive index regions with respect to the square lattice is uniform within the phase modulation layer. A distance between the center of gravity of each of the modified refractive index regions and the corresponding lattice point is individually set according to the predetermined phase distribution. Distances between the centers of gravity of at least two of the modified refractive index regions and the lattice point are different from each other. A lattice spacing of the square lattice and a light emission wavelength A, of the light emission portion satisfy a condition for M-point oscillation. Four-direction in-plane wavenumber vectors each including a wavenumber spread corresponding to an angular spread of light output from the light-emitting device are formed on a reciprocal lattice space of the phase modulation layer. Magnitude of at least one of the in-plane wavenumber vectors is less than 2π/λ. The predetermined phase distribution includes an element for focusing the light output in at least one direction.

In the above-described light-emitting device, the center of gravity of each modified refractive index region is arranged away from the corresponding lattice point of the virtual square lattice, and has an individual rotation angle around the lattice point according to the predetermined phase distribution. Alternatively, the center of gravity of each modified refractive index region is arranged on a straight line passing through the lattice point of the virtual square lattice and inclined to the square lattice, and the distance between the center of gravity of each modified refractive index region and the corresponding lattice point is set individually according to the predetermined phase distribution. With such a structure, it is possible to generate an arbitrarily shaped optical image as an S-iPM laser.

In addition, in this light-emitting device, the lattice spacing of the square lattice and the light emission wavelength of the light emission portion satisfy the condition for M-point oscillation. Normally, in the standing wave state of M-point oscillation, light propagating in the phase modulation layer undergoes total reflection. Therefore, output of both the signal light and zero-order light is suppressed. Here, the signal light is, for example, one or both of the +1-order light and the −1-order light. However, in this light-emitting device, on the reciprocal lattice space of the phase modulation layer, the standing wave undergoes phase modulation by the phase distribution, and forms four-direction in-plane wavenumber vectors each including the wavenumber spread corresponding to the angular spread of the light output. At least one of these in-plane wavenumber vectors has a magnitude smaller than 2π/λ, that is, the light line. In the S-iPM laser, such adjustment of the in-plane wavenumber vectors is possible by applying an ingenious way to the arrangement of each modified refractive index region. When the magnitude of at least one in-plane wavenumber vector is less than 2λ/λ, the in-plane wavenumber vector has a component in the thickness direction of the phase modulation layer, and does not produce total reflection at the interface with air. As a result, part of the signal light is output from the phase modulation layer. However, if the condition for M-point oscillation is satisfied, the zero-order light does not diffract to the direction perpendicular to the plane and is not output from the phase modulation layer into the light line. That is, the above-described light-emitting device can remove the zero-order light contained in the output of the S-iPM laser from within the light line and can output only the signal light.

In addition, in this light-emitting device, the predetermined phase distribution includes the element for focusing the light output. This allows the light-emitting device to output light while focusing the light. In addition, as described above, in the light-emitting device, since the output of zero-order light that does not contribute to light focusing is suppressed, only the signal light that can contribute to light focusing can be output. In this way, the above-described light-emitting device, which can focus light by the light-emitting device itself, can remove optical components for light focusing and miniaturize the light source device.

In the above-described light-emitting device, the element of the predetermined phase distribution may be an element for focusing the light output to at least two focal points. With the light-emitting device, by appropriately designing the element for focusing light included in the predetermined phase distribution, it is also possible to focus the light output from one light-emitting device to at least two focal points. Therefore, at least two optical components for focusing light can be removed, and the light source device can be further miniaturized.

In the above-described light-emitting device, the predetermined phase distribution may include, as the element, a phase distribution obtained by synthesizing a first phase distribution for emitting the light output toward at least two points and a second phase distribution for focusing the light output. For example, such an element allows the light output to be focused to at least two focal points.

In the above-described light-emitting device, the at least two focal points may be arranged in a direction intersecting the thickness direction. In this case, for example, the light-emitting device can be used for purposes such as causing light from each focal point to interfere with each other.

In the above-described light-emitting device, the element of the predetermined phase distribution may be an element for focusing the light output to at least four focal points, and the at least four focal points may be distributed three-dimensionally. In this case, the light-emitting device can be used for purposes such as creating, for example, a three-dimensional, in other words, stereoscopic optical image.

In the above-described light-emitting device, the predetermined phase distribution may be obtained by superimposing a hologram phase distribution forming a plurality of bright spots arranged in a first direction and a lens phase distribution having a light focusing action only in a second direction intersecting the first direction. In this case, a striped optical image with little uneven luminance can be obtained. Such an optical image can improve, for example, measurement precision in three-dimensional shape measurement.

In the above-described light-emitting device, the predetermined phase distribution may be obtained by superimposing a hologram phase distribution forming a plurality of bright spot groups arranged in a first direction and a lens phase distribution having a light focusing action only in a second direction intersecting the first direction. Each of the bright spot groups may include a plurality of bright spots, and light intensity of at least two of the plurality of bright spots may differ from each other. In this case, a striped optical image with little uneven luminance can be obtained. Such an optical image can improve, for example, measurement precision in three-dimensional shape measurement. In this case, each of the bright spot groups may include a first bright spot, a second bright spot, and a third bright spot different in position from each other in the first direction. The second bright spot and the third bright spot may be arranged at positions sandwiching the first bright spot, and the light intensities of the second bright spot and the third bright spot may be less than the light intensity of the first bright spot. This makes it possible to obtain an optical image in which the light intensity increases and decreases in a sinusoidal manner along the first direction.

In the above-described light-emitting device, the predetermined phase distribution may be obtained by superimposing a hologram phase distribution and a lens phase distribution. The hologram phase distribution forms a plurality of bright spots arranged in a first direction. The lens phase distribution has a light focusing action in the first direction and a second direction intersecting the first direction, and has a focal length in the first direction longer than a focal length in the second direction. In this case, a striped optical image with little uneven luminance can be obtained. Such an optical image can improve, for example, measurement precision in three-dimensional shape measurement.

A first light source device according to the present disclosure includes first and second light-emitting devices that are any of the light-emitting devices described above. The element of the predetermined phase distribution of the first light-emitting device focuses first light output from the first light-emitting device toward a first focal point. The element of the predetermined phase distribution of the second light-emitting device focuses second light output from the second light-emitting device toward a second focal point aligned with the first focal point. This light source device causes the first light output and the second light output to interfere with each other to generate an interference fringe.

A second light source device according to the present disclosure includes the above-described light-emitting device that focuses light output to at least two focal points. The element of the predetermined phase distribution of the light-emitting device focuses first light output from the light-emitting device toward a first focal point and focuses second light output from the light-emitting device toward a second focal point. This light source device causes the first light output and the second light output to interfere with each other to generate an interference fringe.

With these light source devices, an interference fringe is generated by the first and second light output emitted toward the first and second focal points, respectively. This interference fringe is an optical image with a sinusoidal increase and decrease in light intensity along a certain direction. Such an optical image can be used, for example, for three-dimensional shape measurement. In addition, the light-emitting device included in these light source devices can be miniaturized as described above. Therefore, the light-emitting device can be disposed even in a very small space, for example, inside the body, enabling three-dimensional shape measurement for a small space that has been previously impossible. The phase distribution for focusing the light output is simpler than the phase distribution for directly generating an optical image containing interference fringes. Therefore, noise generated in the optical image during calculation can be reduced. Therefore, since an optical image having light intensity that increases and decreases in a sinusoidal manner can be generated with high precision, for example, measurement errors in three-dimensional shape measurement can be reduced.

The first light source device may further include an optical system optically coupled to the first and second light-emitting devices. In this case, the first focal point is located between the first light-emitting device and the optical system. The second focal point is located between the second light-emitting device and the optical system. The first light output and the second light output interfere with each other after passing through the optical system. The second light source device may further include an optical system optically coupled to the light-emitting device. In this case, the first and second focal points are located between the light-emitting device and the optical system. The first light output and the second light output interfere with each other after passing through the optical system.

In this way, the first and second light source devices may include the optical system. In this case, it is possible to enlarge the irradiation surface of the optical image having the light intensity that increases and decreases in a sinusoidal manner, regardless of the area of the light emission surface of the light-emitting device.

### Advantageous Effects of Invention

The present disclosure makes it possible to provide a light-emitting device capable of miniaturizing a light source device that outputs light while focusing the light, and a light source device including the light-emitting device.

### BRIEF DESCRIPTION OF DRAWINGS

FIG. 1 is a partial cross-sectional perspective view showing the configuration of a light-emitting device according to one embodiment of the present disclosure.

FIG. 2 is a schematic diagram showing a laminated structure of the light-emitting device.

FIG. 3 is a plan view of a phase modulation layer.

FIG. 4 is an enlarged view of a unit constituent region.

FIG. 5 is a diagram schematically showing a state where light output is output from the light-emitting device of one embodiment.

Part (a) of FIG. 6 is a diagram showing a state where respective focal points are arranged in a direction that intersects the thickness direction of the light-emitting device. Part (b) of FIG. 6 is a diagram showing a state where respective focal points are distributed three-dimensionally.

Parts (a) and (b) of FIG. 7 are diagrams showing a comparison between the light-emitting device of one embodiment and an S-iPM laser of a comparative example.

FIG. 8 is a plan view showing an example in which substantially periodic refractive index structure is applied to a specific region of the phase modulation layer.

FIG. 9 is a diagram for describing coordinate conversion from spherical coordinates to coordinates in the XYZ Cartesian coordinate system.

FIG. 10 is a plan view showing a reciprocal lattice space regarding the phase modulation layer of the light-emitting device that oscillates at an M point.

FIG. 11 is a conceptual diagram for describing a state where diffraction vectors are added to in-plane wavenumber vectors.

FIG. 12 is a diagram for schematically describing peripheral structure of a light line.

FIG. 13 is a diagram conceptually showing one example of phase distribution.

FIG. 14 is a conceptual diagram for describing a state of adding the diffraction vectors to the four-direction in-plane wavenumber vectors from which wavenumber spreads are removed.

FIG. 15 is a plan view of another mode of the phase modulation layer.

FIG. 16 is a diagram showing arrangement of modified refractive index regions in the phase modulation layer shown in FIG. 15.

FIG. 17 is a diagram showing an example of lens phase distribution.

FIG. 18 is a diagram showing the partially enlarged lens phase distribution.

FIG. 19 is a diagram showing results of an experiment in which the light-emitting device of one embodiment is prototyped and a near-field image is captured while moving an objective lens in the Z direction.

FIG. 20 is a diagram showing results of the experiment in which the light-emitting device of one embodiment is prototyped and the near-field image is captured while moving the objective lens in the Z direction.

FIG. 21 is a diagram showing results of producing a normal light-emitting device (LED) without a phase modulation layer and capturing a near-field image in the same manner for comparison.

FIG. 22 is a diagram showing a state where +1-order light and −1-order light are emitted from the phase modulation layer of the light-emitting device.

FIG. 23 is a diagram showing an example of phase distribution including the lens phase distribution and components corresponding to non-zero vectors.

FIG. 24 is a conceptual diagram of a method for dividing hologram phase distribution and lens phase distribution into a real part and an imaginary part, and synthesizing phase in each of the real part and the imaginary part.

Parts (a) and (b) of FIG. 25 are diagrams showing examples of random patterns.

Parts (a) and (b) of FIG. 26 are diagrams showing positions of focal points.

FIG. 27 is a diagram showing near-field images of the light-emitting device produced in the experiment.

FIG. 28 is a diagram showing near-field images of the light-emitting device produced in the experiment.

FIG. 29 is a diagram showing near-field images of the light-emitting device produced in the experiment.

Parts (a) and (b) of FIG. 30 are diagrams showing positions of focal points.

FIG. 31 is a diagram showing near-field images of the light-emitting device produced in the experiment.

FIG. 32 is a diagram showing near-field images of the light-emitting device produced in the experiment.

FIG. 33 is a diagram showing near-field images of the light-emitting device produced in the experiment.

FIG. 34 is a schematic diagram showing the configuration of a three-dimensional measurement system according to a second embodiment.

FIG. 35 is a diagram schematically showing a light source device as one example of the configuration of a light source device.

FIG. 36 is a diagram schematically showing the light source device as another example of the configuration of the light source device.

FIG. 37 is a diagram showing an interference optical image on an image-forming surface, that is, a pattern of measurement light.

FIG. 38 is a schematic diagram partially showing the configuration of a light source device according to a comparative example.

FIG. 39 is a diagram schematically showing the configuration when an angle θa of the emission direction is made small.

FIG. 40 is a schematic diagram partially showing the configuration of a light source device according to a modification.

Parts (a) and (b) of FIG. 41 are diagrams for describing effects of providing a mask.

FIG. 42 is a diagram showing an example of lens phase distribution for focusing light only in one direction.

Part (a) of FIG. 43 is a diagram schematically showing an example of an optical image formed on one imaginary plane only by hologram phase distribution. Part (b) of FIG. 43 is a diagram schematically showing an optical image obtained by superimposing the lens phase distribution shown in FIG. 42 on the hologram phase distribution forming the optical image shown in part (a).

FIG. 44 is a far-field image of a striped optical image emitted from the prototype light-emitting device.

FIG. 45 shows a far-field image when a striped optical image is formed only by the hologram phase distribution without using the lens phase distribution for comparison.

Parts (a) and (b) of FIG. 46 are diagrams conceptually showing an operation for forming a striped optical image different from that shown in FIG. 43.

Parts (a) and (b) of FIG. 47 are diagrams showing an aspect similar to an aspect shown in FIG. 46.

FIG. 48 is a far-field image of the striped optical image emitted from the prototype light-emitting device.

Parts (a) and (b) of FIG. 49 are diagrams showing another aspect similar to the aspect shown in FIG. 46.

FIG. 50 is a far-field image of the striped optical image emitted from the prototype light-emitting device.

FIG. 51 is a diagram showing an example of a lens phase distribution in which the focal length in the X direction is longer than the focal length in the Y direction.

Part (a) of FIG. 52 is a diagram schematically showing an example of an optical image formed only by the hologram phase distribution, and showing an optical image as in part (a) of FIG. 43. Part (b) of FIG. 52 is a diagram schematically showing an optical image obtained by superimposing the lens phase distribution shown in FIG. 51 on the hologram phase distribution forming the optical image shown in part (a).

FIG. 53 is a far-field image of the striped optical image emitted from the prototype light-emitting device.

### DESCRIPTION OF EMBODIMENTS

Specific examples of a light-emitting device and a light source device of the present disclosure will be described below with reference to the drawings. The present invention is not limited to these examples. The present invention is indicated by the claims, and it is intended to include all changes within the meaning and the scope equivalent to the claims. In the following description, the same reference numerals will be applied to the same elements in description of the drawings, and redundant description thereof will be omitted.

### First Embodiment

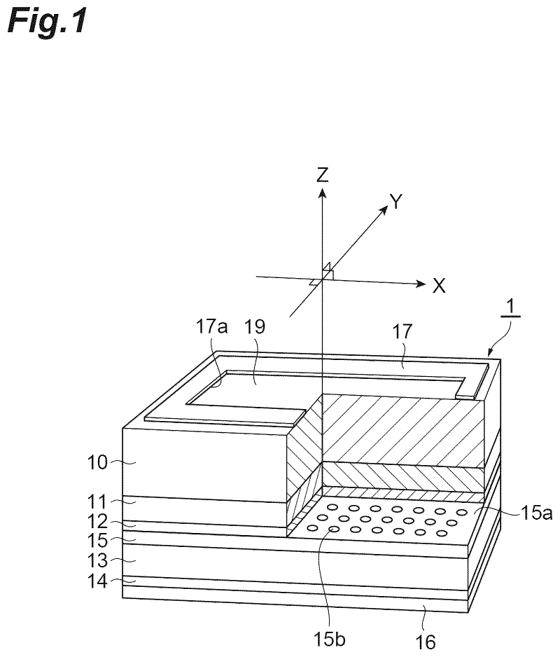

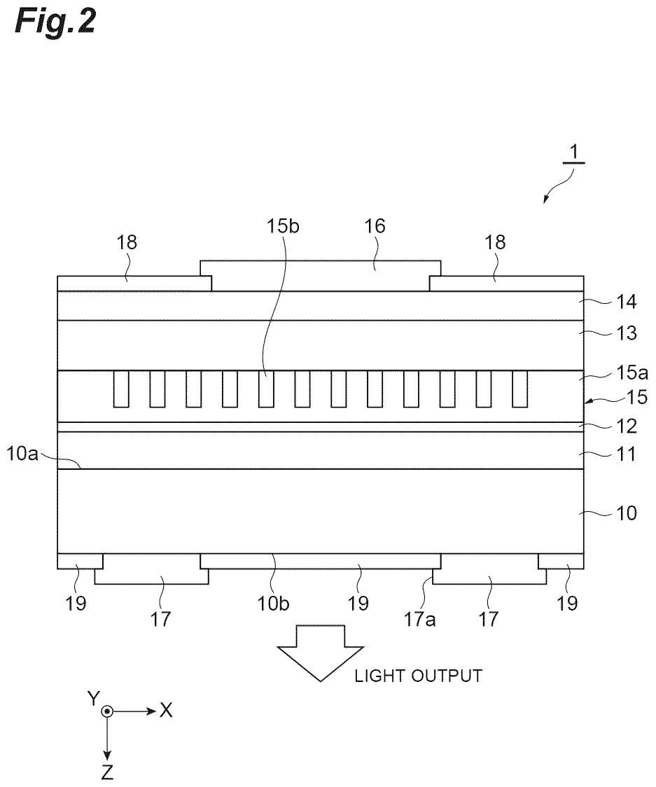

FIG. 1 is a partial cutout perspective view showing the configuration of a light-emitting device 1 according to one embodiment of the present disclosure. FIG. 2 is a schematic diagram showing a laminated structure of the light-emitting device 1. In FIGS. 1 and 2, the XYZ Cartesian coordinate system is defined in which the axis extending in the thickness direction of the light-emitting device 1 at the center of the light-emitting device 1 is the Z axis.

The light-emitting device 1 is a laser light source that forms a standing wave in the XY plane direction and outputs a phase-controlled plane wave in a direction intersecting the thickness direction. The light-emitting device 1 is an S-iPM laser and can output an arbitrary-shaped optical image in a direction perpendicular to a main surface 10a of a semiconductor substrate 10, that is, the Z direction, or in a direction inclined to the Z direction, or both.

As shown in FIGS. 1 and 2, the light-emitting device 1 includes an active layer 12 serving as a light emission portion provided on the semiconductor substrate 10, one pair of cladding layers 11 and 13 sandwiching the active layer 12, and a contact layer 14 provided on the cladding layer 13. The semiconductor substrate 10, the cladding layers 11 and 13, and the contact layer 14 include a compound semiconductor, for example, GaAs-based semiconductor, InP-based semiconductor, or nitride-based semiconductor. The energy bandgap of the cladding layer 11 and the energy bandgap of the cladding layer 13 are larger than the energy bandgap of the active layer 12. The thickness direction of the semiconductor substrate 10, the cladding layer 11, the active layer 12, the cladding layer 13, and the contact layer 14 agrees with the Z-axis direction.

The light-emitting device 1 further includes a phase modulation layer 15 optically coupled to the active layer 12. In the present embodiment, the phase modulation layer 15 is provided between the active layer 12 and the cladding layer 13. The thickness direction of the phase modulation layer 15 agrees with the Z-axis direction. The phase modulation layer 15 may be provided between the cladding layer 11 and the active layer 12. A light guide layer may be provided in one or both of between the active layer 12 and the cladding layer 13, and between the active layer 12 and the cladding layer 11, if necessary. The light guide layer may include a carrier barrier layer for efficiently confining carriers in the active layer 12.

The phase modulation layer 15 includes a base region 15a and a plurality of modified refractive index regions 15b. The base region 15a includes a first refractive index medium. The plurality of modified refractive index regions 15b includes a second refractive index medium with a refractive index different from a refractive index of the first refractive index medium and exists within the base region 15a. The plurality of modified refractive index regions 15b includes a lattice-like substantially periodic structure. When the equivalent refractive index of a mode is n and the lattice spacing is a, the wavelength λ₀ selected by the phase modulation layer 15 is represented as λ₀=(√2)a×n. This wavelength Xo is included in the light emission wavelength range of the active layer 12. The phase modulation layer 15 can select and externally output a band-edge wavelength near the wavelength Xo out of the light emission wavelength of the active layer 12. The light incident in the phase modulation layer 15 forms a predetermined mode within the phase modulation layer 15 according to the arrangement of the modified refractive index regions 15b, and is emitted externally from the surface of the light-emitting device 1 as a laser beam.

The light-emitting device 1 further includes an electrode 16 provided on the contact layer 14 and an electrode 17 provided on a back surface 10b of the semiconductor substrate 10. The electrode 16 forms an ohmic contact with the contact layer 14. The electrode 17 forms an ohmic contact with the semiconductor substrate 10. The electrode 17 has an opening 17a in the central region of the back surface 10b. The electrode 16 is provided in the central region of the front surface of the contact layer 14. Parts on the contact layer 14 except the electrode 16 are covered with a protective film 18 (see FIG. 2). Parts of the contact layer 14 that are not in contact with the electrode 16 may be removed for restricting the current range. A region of the back surface 10b of the semiconductor substrate 10 other than the region where the electrode 17 is provided is covered with an anti-reflective film 19 including the inside of the opening 17a. The anti-reflective film 19 in other regions except the opening 17a may be removed.

In the light-emitting device 1, when a drive current is supplied between the electrode 16 and the electrode 17, recombination of electrons and holes occurs within the active layer 12, causing the active layer 12 to emit light. Electrons and holes that contribute to this light emission and the light generated in the active layer 12 are efficiently confined between the cladding layer 11 and the cladding layer 13.

The light emitted from the active layer 12 enters the inside of the phase modulation layer 15 to form a predetermined mode according to the lattice structure inside the phase modulation layer 15. Part of the laser beam emitted from the phase modulation layer 15 passes through the opening 17a from the back surface 10b and is directly output to the outside of the light-emitting device 1. The rest of the laser beam emitted from the phase modulation layer 15 is reflected by the electrode 16, and then passes through the opening 17a from the back surface 10b and is output to the outside of the light-emitting device 1. At this time, a signal light included in the laser beam is emitted in an arbitrary direction including the direction perpendicular to the main surface 10a and a direction inclined to the direction perpendicular to the main surface 10a.

Light output from the light-emitting device 1 is composed of signal light. The signal light is mainly +1-order diffracted light or −1-order diffracted light of the laser beam, or both. Hereinafter, the +1-order diffracted light will be referred to as +1-order light, and the −1-order diffracted light will be referred to as −1-order light. As will be described later, the output of zero-order light of the laser beam is suppressed from the phase modulation layer 15 of the present embodiment.

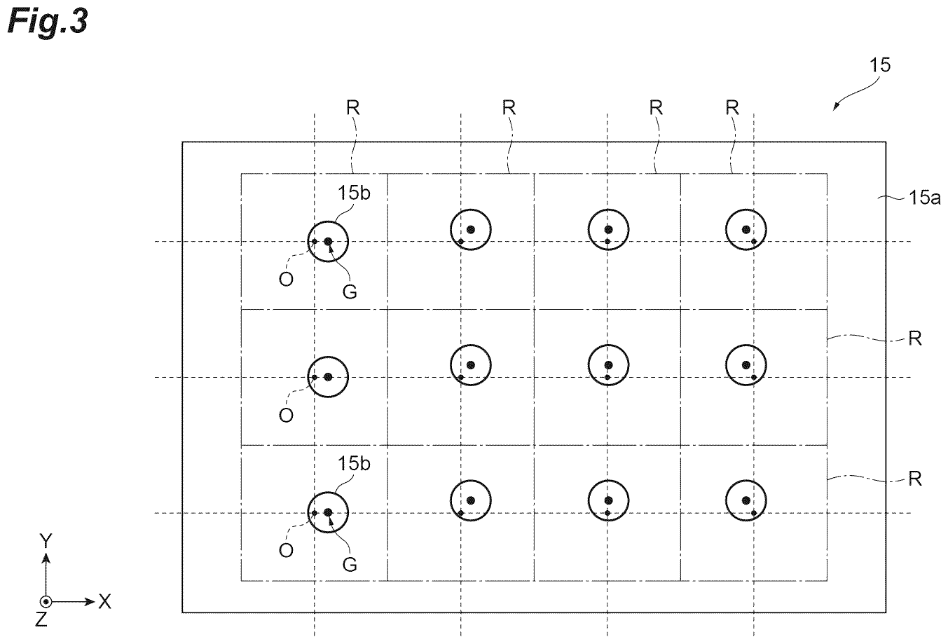

FIG. 3 is a plan view of the phase modulation layer 15. As shown in the figure, the phase modulation layer 15 includes the base region 15a and the plurality of modified refractive index regions 15b. The base region 15a includes a first refractive index medium. The plurality of modified refractive index regions 15b includes the second refractive index medium with a refractive index different from a refractive index of the first refractive index medium. In FIG. 3, a virtual square lattice in the XY-plane is set on the phase modulation layer 15. One side of the square lattice is parallel to the X axis, and the other side is parallel to the Y axis. Square-shaped unit constituent regions R centered on a lattice point O of the square lattice are arranged in a two-dimensional form over multiple columns along the X axis and multiple rows along the Y axis. The XY coordinates of each unit constituent region R are defined by the position of the center of gravity of each unit constituent region R. The position of the center of gravity agrees with the lattice point O of the virtual square lattice. For example, one modified refractive index region 15b is provided in each unit constituent region R. The planar shape of the modified refractive index region 15b is, for example, a circular shape. The lattice point O may be located outside the modified refractive index region 15b or contained within the modified refractive index region 15b.

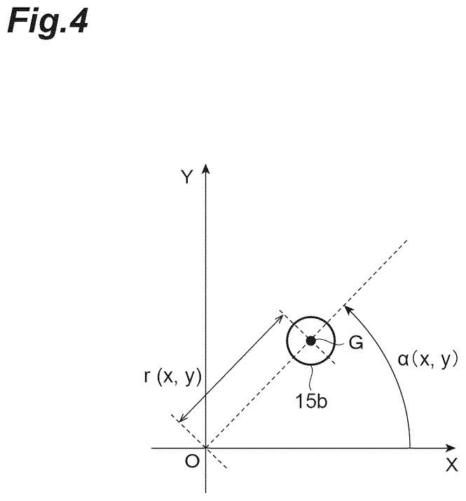

FIG. 4 is an enlarged view of the unit constituent region R. As shown in the figure, each of the modified refractive index regions 15b has the center of gravity G. Here, α(x, y) is the angle between the vector from the lattice point to the center of gravity G and the X axis. The angle α(x, y) is the rotation angle of the center of gravity G of the modified refractive index region 15b around the lattice point O. x indicates the position of the x-th lattice point on the X axis, and y indicates the position of the y-th lattice point on the Y axis. When the rotation angle α is 0°, the direction of the vector connecting the lattice point O to the center of gravity G agrees with the positive direction of the X axis. r(x, y) is the length of the vector connecting the lattice point O to the center of gravity G. In one example, r(x, y) is constant across the phase modulation layer 15, regardless of x and y.

As shown in FIG. 3, the direction of the vector connecting the lattice point O to the center of gravity G, that is, the rotation angle α is individually set for each lattice point O according to phase distribution φ(x, y) corresponding to the desired shape of the light output. The rotation angles α of the centers of gravity G of at least two modified refractive index regions 15b are different from each other. In the present disclosure, such an arrangement form of the center of gravity G is referred to as a first arrangement form. The phase distribution φ(x, y) has a specific value for each position determined by the x and y values, but is not necessarily represented by a specific function. The distribution of the rotation angle α(x, y) is determined by extracting the phase distribution φ(x, y) from complex amplitude distribution obtained by performing Fourier transform on the desired shape of the light output. When obtaining the complex amplitude distribution from the desired shape of the light output, iterative algorithm such as the Gerchberg-Saxton (GS) method, which is commonly used in calculation for generating holograms, is preferably applied. In this case, it is possible to improve the reproducibility of the beam pattern.

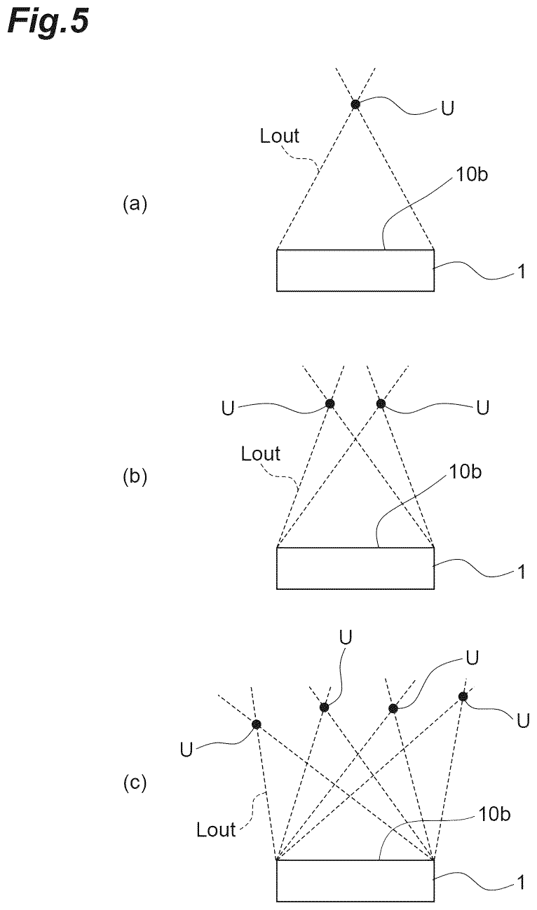

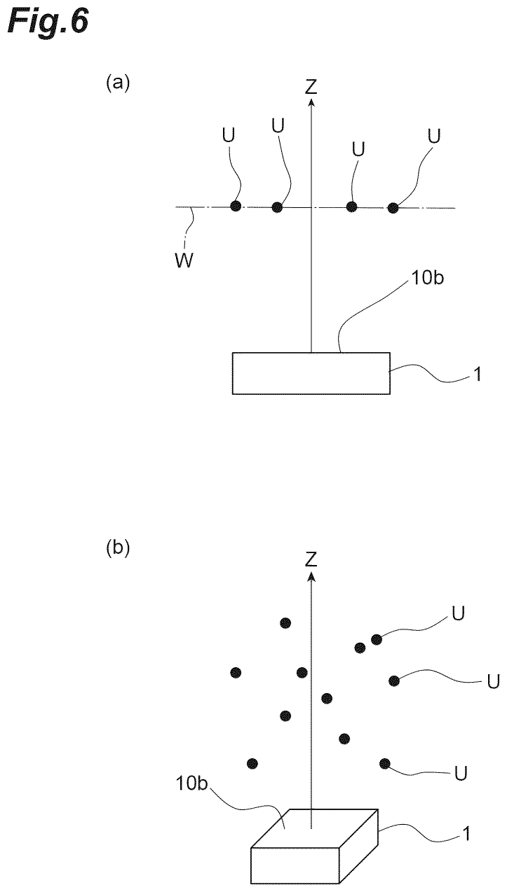

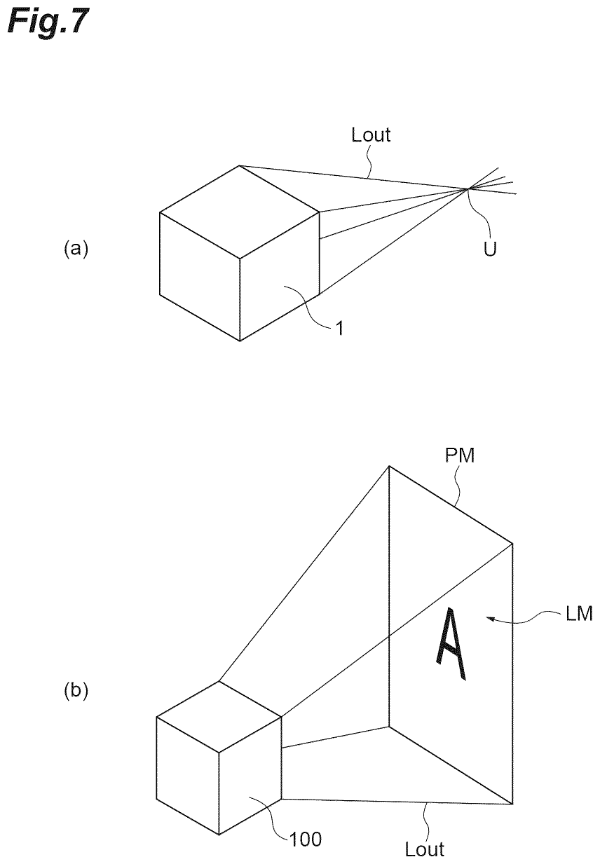

Parts (a) to (c) of FIG. 5 are diagrams schematically showing a state where light output Lout is output from the light-emitting device 1 of the present embodiment. As shown in the figure, the light-emitting device 1 of the present embodiment performs a self-focusing operation to emit the light output Lout while focusing the light as a desired shape of the light output Lout. As shown in parts (a) to (c) of FIG. 5, the number of focal points U of the light output Lout may be one, two, or three or more. When the number of focal points U is two or more, as shown in part (a) of FIG. 6, respective focal points U may be arranged in a direction intersecting or orthogonal to the thickness direction of the light-emitting device 1, that is, the Z direction, or may be distributed on a plane W intersecting or orthogonal to the Z direction. Alternatively, when the number of focal points U is four or more, respective focal points U may be distributed three-dimensionally (stereoscopically) as shown in part (b) of FIG. 6. The distribution of the phase distribution φ(x, y) and the distribution of the rotation angle α(x, y) are determined according to the distribution of the focal points U of the light output Lout.

FIG. 7 is a diagram showing a comparison between the light-emitting device 1 of the present embodiment and an S-iPM laser of a comparative example. As shown in part (a) of FIG. 7, the light-emitting device 1 of the present embodiment emits the light output Lout while focusing the light. In contrast, as shown in part (b) of FIG. 7, the S-iPM laser 100 of the comparative example emits the light output Lout while diffusing the light with a certain spread angle to form an optical image LM on a certain projection plane PM.

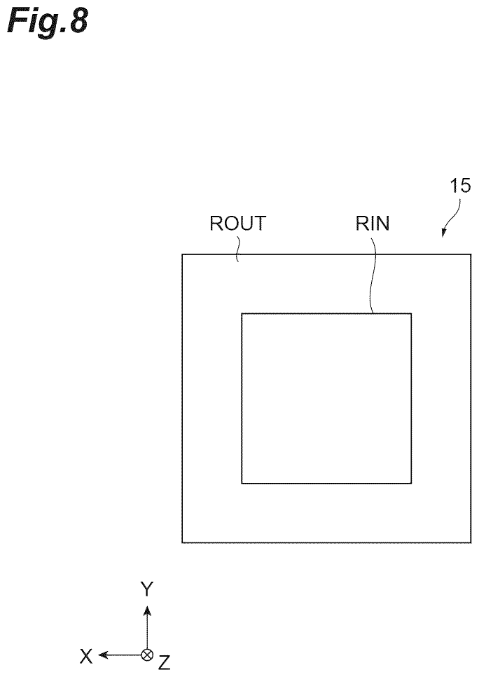

FIG. 8 is a plan view showing an example in which substantially periodic refractive index structure is applied to a specific region of the phase modulation layer 15. In the example shown in FIG. 8, the substantially periodic structure for emitting a desired optical image, for example, the structure shown in FIG. 3 is formed inside a square inner region RIN. Meanwhile, the modified refractive index regions 15b each having a perfect circle where the position of the lattice point of the square lattice agrees with the center of gravity are arranged in an outer region ROUT surrounding the inner region RIN. In the inner region RIN and the outer region ROUT, the lattice spacing a of the square lattice set virtually is the same as each other. Since light is distributed in the outer region ROUT as well, the structure shown in FIG. 8 can suppress generation of high-frequency noise produced by the abrupt change in light intensity at the periphery of the inner region RIN, so-called window function noise. In addition, light leakage in a direction perpendicular to the thickness direction can be suppressed, and a reduction in a threshold current can be expected. Not limited to this example, the substantially periodic structure for emitting a desired optical image, for example, the structure shown in FIG. 3 may be formed over the entire region of the phase modulation layer 15.

To emit the light output Lout while focusing the light and to obtain a desired distribution of the focal points U, the distribution of the rotation angle α(x, y) of the modified refractive index regions 15b in the phase modulation layer 15 is determined by the following procedure.

The XYZ Cartesian coordinate system defined by the Z axis that agrees with the normal direction and the X-Y plane that agrees with one surface of the phase modulation layer 15 including the plurality of modified refractive index regions 15b is defined. As a first precondition, a virtual square lattice including M₁×N₁ unit constituent regions R each having a square shape is set on the X-Y plane. Each of M₁ and N₁ is an integer of 1 or more.

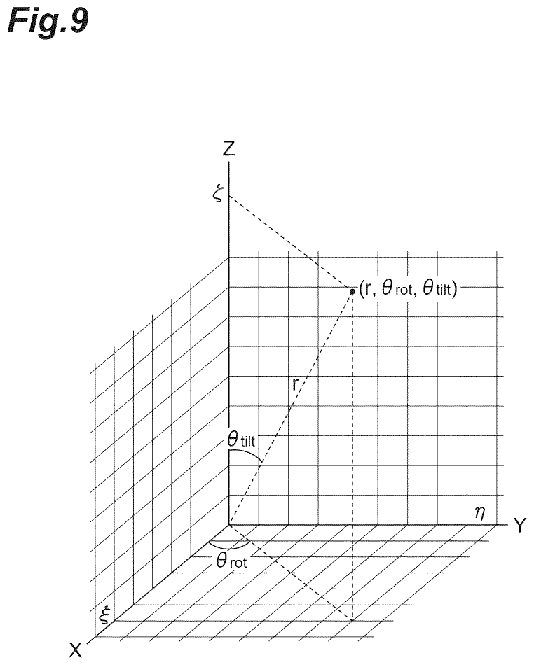

As shown in FIG. 9, spherical coordinates (r, θᵣₒₜ, θₜᵢₗₜ) defined by a length of radial diameter r, a tilt angle θₜᵢₗₜ from the Z axis, and a rotation angle θᵣₒₜ from the X axis specified on the X-Y plane are defined. As a second precondition, it is assumed that coordinates (ξ, η, ζ) in the XYZ Cartesian coordinate system satisfy the relationship expressed by the following Formulas (1) to (3) for the spherical coordinates (r, θᵣₒₜ, θₜᵢₗₜ).

FIG. 9 is a diagram for describing coordinate conversion from the spherical coordinates (r, θᵣₒₜ, θₜᵢₗₜ) to the coordinates (ξ, η, ζ) in the XYZ Cartesian coordinate system. An optical image in design on a predetermined plane set in the XYZ Cartesian coordinate system, which is a real space, is represented by the coordinates (ξ, η, ζ).

[Formula 1]

ξ=r sin θₜᵢₗₜ cos θᵣₒₜ (1)

[Formula 2]

η=r sin θₜᵢₗₜ sin θᵣₒₜ (2)

[Formula 3]

ζ=r cos θₜᵢₗₜ (3)

It is assumed that the light emitted from the light-emitting device 1 is a set of bright spots pointing in the direction defined by the angles θₜᵢₗₜ and θᵣₒₜ. At this time, it is assumed that the angles θₜᵢₗₜ and θᵣₒₜ are converted into coordinate values kx and ky. The coordinate value kx is a normalized wavenumber defined by the following Formula (4), and is a coordinate value on the Kₓ axis corresponding to the X axis. The coordinate value ky is a normalized wavenumber defined by the following Formula (5), and is a coordinate value on the K_{y} axis corresponding to the Y axis and orthogonal to the Kₓ axis. The normalized wavenumber means a wavenumber normalized by setting the wavenumber 2π/a corresponding to the lattice spacing of the virtual square lattice to 1.0. At this time, in the wavenumber space defined by the Kₓ and K_{y} axes, the specific wavenumber range including the beam pattern corresponding to the optical image includes M₂×N₂ image regions FR each having a square shape. Each of M₂ and N₂ is an integer of 1 or more. The integer M₂ does not need to agree with the integer M₁. The integer N₂ does not need to agree with the integer N₁. Formulas (4) and (5) are disclosed, for example, in Y. Kurosaka et al., “Effects of non-lasing band in two-dimensional photonic-crystal lasers clarified using omnidirectional band structure”, Opt. Express 20, 21773-21783 (2012).

$$[ Formula 4 ]$$

$${k}_{x} = \frac{a}{λ} sin {θ}_{tilt} cos {θ}_{rot} \qquad ( 4 )$$

$$[ Formula 5 ]$$

$${k}_{y} = \frac{a}{λ} sin {θ}_{tilt} sin {θ}_{rot} \qquad ( 5 )$$

a: lattice constant of virtual square lattice

λ: oscillation wavelength of light-emitting device 1

In the wavenumber space, the image region FR(kx, ky) is specified by the coordinate component kx in the Kₓ-axis direction and the coordinate component ky in the K_{y}-axis direction. The coordinate component kx is an integer equal to or greater than 0 and equal to or less than M₂−1. The coordinate component ky is an integer equal to or greater than 0 and equal to or less than N₂−1. The unit constituent region R(x, y) on the X-Y plane is specified by a coordinate component x in the X-axis direction and a coordinate component y in the Y-axis direction. The coordinate component x is an integer equal to or greater than 0 and equal to or less than M₁−1. The coordinate component y is an integer equal to or greater than 0 and equal to or less than N₁−1. As a third precondition, a complex amplitude F(x, y) obtained by performing two-dimensional inverse discrete Fourier transform on each image region FR(kx, ky) to the unit constituent region R(x, y) is given by the following Formula (6) with j as an imaginary unit. The complex amplitude F(x, y) is defined by the following Formula (7) when the amplitude term is A(x, y) and the phase term is φ(x, y). As a fourth precondition, the unit constituent region R(x, y) is defined by the s axis and t axis. The s axis and t axis are parallel to the X axis and Y axis respectively, and are orthogonal to each other at the lattice point O(x, y) that is the center of the unit constituent region R(x, y).

$$[ Formula 6 ]$$

$$F ( x , y ) = {\sum }_{{k}_{x} = 0}^{M 2 - 1} {\sum }_{{k}_{y} = 0}^{N 2 - 1} FR ( {k}_{x} , {k}_{y} ) exp [ j 2 π ( \frac{{k}_{x}}{M 2} x + \frac{{k}_{y}}{N 2} y ) ] \qquad ( 6 )$$

$$[ Formula 7 ]$$

$$F ( x , y ) = A ( x , y ) \times exp [ j ϕ ( x , y ) ] \qquad ( 7 )$$

Under the first to fourth preconditions, the phase modulation layer 15 is configured to satisfy the following fifth and sixth conditions. The fifth condition is that the center of gravity G is placed away from the lattice point O(x, y) in the unit constituent region R(x, y). The sixth condition is that the line segment length r₂((x, y) from the lattice point O(x, y) to the corresponding center of gravity G is set to a common value in each of M₁×N₁ unit constituent regions R. In addition, the sixth condition is that the angle α(x, y) formed between the line segment connecting the lattice point O(x, y) to the corresponding center of gravity G, and the s axis satisfies the following relationship.

α(x,y)=C×ϕ(x,y)+B

C: constant of proportionality, for example, 180°/π

B: arbitrary constant, for example, 0

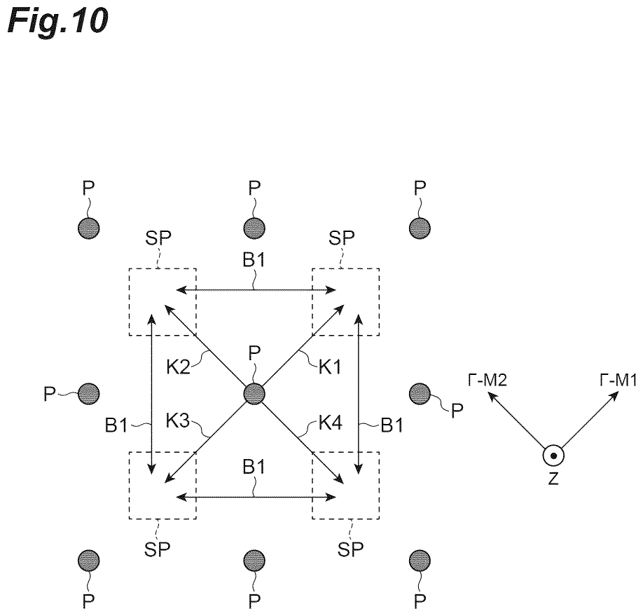

Next, M-point oscillation of the light-emitting device 1 will be described. For M-point oscillation of the light-emitting device 1, the lattice spacing a of the virtual square lattice, the light emission wavelength λ of the active layer 12, and the mode equivalent refractive index n preferably satisfy the condition λ=(√2)n×a. FIG. 10 is a plan view showing a reciprocal lattice space regarding the phase modulation layer of the light-emitting device that performs M-point oscillation. The point P in the figure represents a reciprocal lattice point. An arrow B1 in the figure represents a basic reciprocal lattice vector, and arrows K1, K2, K3, and K4 represent four in-plane wavenumber vectors. The in-plane wavenumber vectors K1 to K4 each have a wavenumber spread SP due to the distribution of the rotation angle α(x, y).

The magnitude of the in-plane wavenumber vectors K1 to K4, that is, the magnitude of the standing wave in the in-plane direction is smaller than the magnitude of the basic reciprocal lattice vector B1. Therefore, the vector sum of the in-plane wavenumber vectors K1 to K4 and the basic reciprocal lattice vector B1 is not zero. Since the wavenumber in the in-plane direction cannot become 0 due to diffraction, diffraction in the direction perpendicular to the plane, that is, in the Z-axis direction does not occur. As it is, not only the zero-order light in the direction perpendicular to the plane, that is, in the Z-axis direction, but also the +1-order light and −1-order light in a direction inclined to the Z-axis direction are not output in the light-emitting device 1 of M-point oscillation.

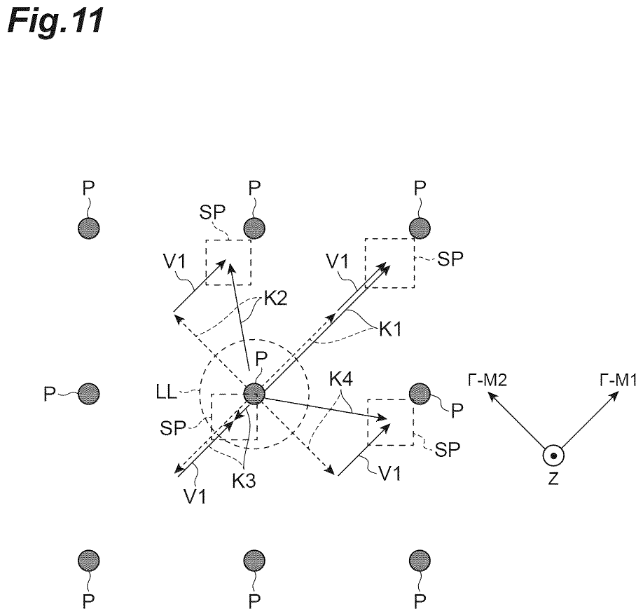

In the present embodiment, by applying the following ingenious way to the phase modulation layer 15 in the light-emitting device 1 of M-point oscillation, part of the +1-order light and the −1-order light is output without output of the zero-order light. That is, as shown in FIG. 11, a diffraction vector V1 having a certain magnitude and direction is added to the in-plane wavenumber vectors K1 to K4. With this addition, the magnitude of at least one of the in-plane wavenumber vectors K1 to K4 (in-plane wavenumber vector K3 in the figure) is made smaller than 2π/λ. λ is the wavelength of light output from the active layer 12. In other words, at least one of the in-plane wavenumber vectors K1 to K4 after the diffraction vector V1 is added is contained in the light line LL. The light line LL is a circular region with a radius of 2π/λ.

The in-plane wavenumber vectors K1 to K4 indicated by dashed lines in FIG. 11 represent before addition of the diffraction vector V1. The in-plane wavenumber vectors K1 to K4 indicated by solid lines in FIG. 11 represent after addition of the diffraction vector V1. The light line LL corresponds to total reflection conditions. A wavenumber vector having a magnitude that can be contained in the light line LL has a component in the direction perpendicular to the plane, that is, in the Z-axis direction. In one example, the direction of the diffraction vector V1 is along the Γ-M1 axis or the Γ-M2 axis. The magnitude of the diffraction vector V1 is within the range from 2λ/(√2)a−2π/λ to 2π/(√2)a+2π/λ, and one example is 2π/(√2)a.

Subsequently, the magnitude and direction of the diffraction vector V1 for containing at least one of the in-plane wavenumber vectors K1 to K4 in the light line LL will be examined. The following Formulas (8) to (11) show the in-plane wavenumber vectors K1 to K4 before the diffraction vector V1 is added, respectively.

$$[ Formula 8 ]$$

$$K 1 = ( \frac{π}{a} + Δ kx , \frac{π}{a} + Δ ky ) \qquad ( 8 )$$

$$[ Formula 9 ]$$

$$K 2 = ( - \frac{π}{a} + Δ kx , \frac{π}{a} + Δ ky ) \qquad ( 9 )$$

$$[ Formula 10 ]$$

$$K 3 = ( - \frac{π}{a} + Δ kx , - \frac{π}{a} + Δ ky ) \qquad ( 10 )$$

$$[ Formula 11 ]$$

$$K 4 = ( \frac{π}{a} + Δ kx , - \frac{π}{a} + Δ ky ) \qquad ( 11 )$$

Spreads Δkx and Δky of the in-plane wavenumber vector satisfy the following Formulas (12) and (13), respectively. The maximum value of the x-axis spread Δkxₘₐₓ and the maximum value of the y-axis spread Δkyₘₐₓ of the in-plane wavenumber vector are defined by a design angular spread of an optical image.

[Formula 12]

−Δkxₘₐₓ≤Δkx≤Δkxₘₐₓ (12)

[Formula 13]

−Δkyₘₐₓ≤Δky≤Δkyₘₐₓ (13)

The diffraction vector V1 is represented as in the following Formula (14). At this time, the following Formulas (15) to (18) show the in-plane wavenumber vectors K1 to K4 after the diffraction vector V1 is added, respectively.

$$[ Formula 14 ]$$

$$V 1 = ( Vx , Vy ) \qquad ( 14 )$$

$$[ Formula 15 ]$$

$$K 1 = ( \frac{π}{a} + Δ kx + Vx , \frac{π}{a} + Δ ky + Vy ) \qquad ( 15 )$$

$$[ Formula 16 ]$$

$$K 2 = ( - \frac{π}{a} + Δ kx + Vx , \frac{π}{a} + Δ ky + Vy ) \qquad ( 16 )$$

$$[ Formula 17 ]$$

$$K 3 = ( - \frac{π}{a} + Δ kx + Vx , - \frac{π}{a} + Δ ky + Vy ) \qquad ( 17 )$$

$$[ Formula 18 ]$$

$$K 4 = ( \frac{π}{a} + Δ kx + Vx , - \frac{π}{a} + Δ ky + Vy ) \qquad ( 18 )$$

In Formulas (15) to (18), when considering that any of the in-plane wavenumber vectors K1 to K4 is contained in the light line LL, the relationship of the following Formula (19) holds.

$$[ Formula 19 ]$$

$${( \pm \frac{π}{a} + Δ kx + Vx )}^{2} + {( \pm \frac{π}{a} + Δ ky + Vy )}^{2} < {( \frac{2 π}{λ} )}^{2} \qquad ( 19 )$$

That is, by adding the diffraction vector V1 that satisfies Formula (19), any of the in-plane wavenumber vectors K1 to K4 is contained in the light line LL, and part of the +1-order light and the −1-order light is output.

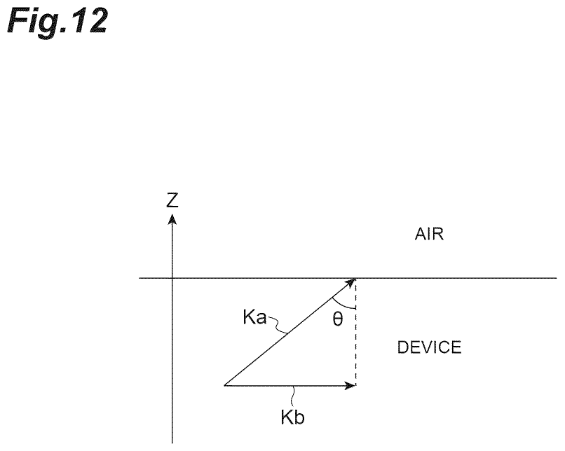

The magnitude, that is, the radius of the light line LL is set to 2π/λ for the following reason. FIG. 12 is a diagram for schematically describing peripheral structure of the light line LL. This figure shows the boundary between the device and air in the Z direction. The magnitude of the wavenumber vector of light in vacuum is 2π/λ. When light propagates through the device medium as shown in FIG. 12, the magnitude of a wavenumber vector Ka in a medium of the refractive index n is 2πn/λ. At this time, considering the wavenumber conservation law, in order for the light to propagate through the boundary between the device and the air, wavenumber components parallel to the boundary need to be continuous.

When the wavenumber vector Ka and the Z axis form an angle θ in FIG. 12, the length of the wavenumber vector projected onto the plane, that is, an in-plane wavenumber vector Kb is (2πn/λ)sin θ. Since the refractive index n of a medium is greater than 1 in general, the wavenumber conservation law does not hold at an angle θ where the in-plane wavenumber vector Kb in the medium is greater than 2π/λ. At this time, the light is totally reflected and cannot be taken out to the air side. The magnitude of the wavenumber vector corresponding to this total reflection condition is the magnitude of the light line LL, that is, 2π/λ.

As one example of a specific method for adding the diffraction vector V1 to the in-plane wavenumber vectors K1 to K4, a method for superimposing a phase distribution φ₂(x, y) unrelated to the desired light output shape on a phase distribution φ₁(x, y) according to the desired light output shape is considered. In this case, the phase distribution φ(x, y) of the phase modulation layer 15 is represented as φ(x, y)=φ₁(x, y)+φ₂(x, y). φ₁(x, y) corresponds to the phase of the complex amplitude when the desired shape of the light output undergoes Fourier transform, as described above. φ₂(x, y) is a phase distribution for adding the diffraction vector V1 that satisfies the above Formula (19).

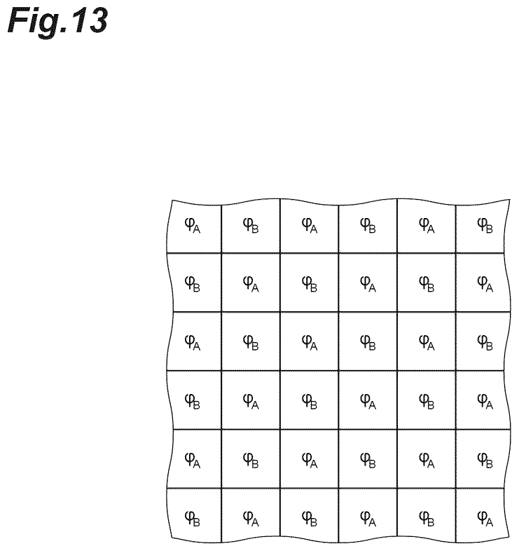

FIG. 13 is a diagram conceptually showing one example of the phase distribution φ₂(x, y). In the example of the figure, a first phase value φ_{A} and a second phase value φ_{B} different from the first phase value φ_{A} are arranged in a checkered pattern. In one example, the phase value φ_{A} is 0 (rad) and the phase value φ_{B} is π (rad). In this case, the difference between the first phase value (pa and the second phase value cps is Tr. With such an arrangement of phase values, the diffraction vector V1 along the δ-M1 axis or the δ-M2 axis can be suitably implemented. Since V1=(±π/a, ±π/a) for the checkered arrangement, the diffraction vector V1 and any one of the in-plane wavenumber vectors K1 to K4 shown in FIG. 11 exactly cancel each other. Therefore, the axis of symmetry of the +1-order light and the −1-order light agrees with the Z direction, that is, the direction perpendicular to the in-plane direction of the phase modulation layer 15. The angular distribution θ₂(x, y) corresponding to the phase distribution φ₂(x, y) of the diffraction vector V is represented by an inner product of the diffraction vector V(Vx, Vy) and the position vector r(x, y), and is given by the following Formula.

θ₂(x,y)=V·r=Vx·x+Vy·y

Therefore, for V=V1, the phase values are 0 (rad) and π (rad) when the position vector is r(xa, ya). Both x and y are integers. Meanwhile, as described above, if at least one of the in-plane wavenumber vectors K1 to K4 is in the range within the light line LL, the diffraction vector V1 may be shifted from (±π/a, ±π/a).

In the present embodiment, when the wavenumber spread based on the angular spread of the light output is included in a circle with a radius Δk centered on a certain point on the wavenumber space, it is also possible to consider simply as follows. By adding the diffraction vector V1 to the four-direction in-plane wavenumber vectors K1 to K4, the magnitude of at least one of the four-direction in-plane wavenumber vectors K1 to K4 is made smaller than 2π/λ, that is, the light line LL. This can be considered as making the magnitude of at least one of the four-direction in-plane wavenumber vectors K1 to K4 smaller than a value {(2π/λ)−Δk} obtained by subtracting the wavenumber spread Δk from 2π/λ, by adding the diffraction vector V1 to the four-direction in-plane wavenumber vectors K1 to K4 excluding the wavenumber spread Δk.

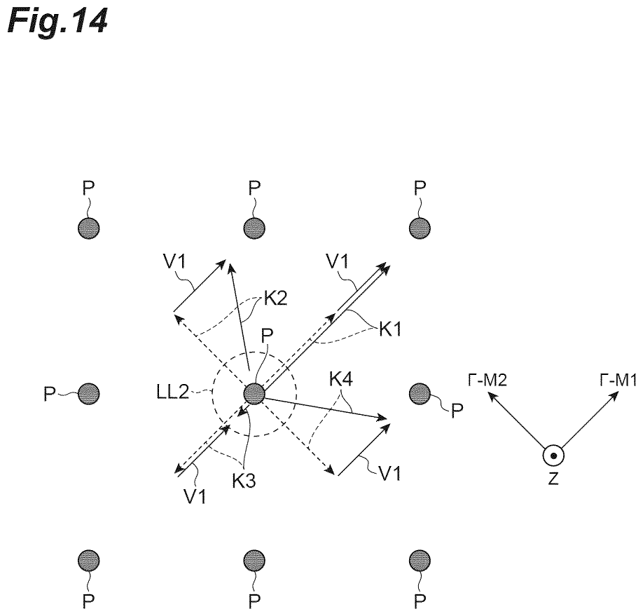

FIG. 14 is a diagram conceptually showing the above-described idea. As shown in the figure, when the diffraction vector V1 is added to the in-plane wavenumber vectors K1 to K4 excluding the wavenumber spread Δk, the magnitude of at least one of the in-plane wavenumber vectors K1 to K4 is made smaller than {(2π/λ)−Δk}. In FIG. 14, a region LL2 is a circular region with the radius of {(2π/λ)−Δk}. The in-plane wavenumber vectors K1 to K4 indicated by dashed lines in FIG. 14 represent before addition of the diffraction vector V1. The in-plane wavenumber vectors K1 to K4 indicated by solid lines in FIG. 14 represent after addition of the diffraction vector V1. The region LL2 corresponds to the total reflection condition considering the wavenumber spread Δk. A wavenumber vector having a magnitude that is contained in the region LL2 also propagates in the direction perpendicular to the plane, that is, in the Z-axis direction.

The present embodiment describes the magnitude and direction of the diffraction vector V1 for containing at least one of the in-plane wavenumber vectors K1 to K4 within the region LL2. The following Formulas (20) to (23) show the in-plane wavenumber vectors K1 to K4 before the diffraction vector V1 is added, respectively.

$$[ Formula 20 ]$$

$$K 1 = ( \frac{π}{a} , \frac{π}{a} ) \qquad ( 20 )$$

$$[ Formula 21 ]$$

$$K 2 = ( - \frac{π}{a} , \frac{π}{a} ) \qquad ( 21 )$$

$$[ Formula 22 ]$$

$$K 3 = ( - \frac{π}{a} , - \frac{π}{a} ) \qquad ( 22 )$$

$$[ Formula 23 ]$$

$$K 4 = ( \frac{π}{a} , - \frac{π}{a} ) \qquad ( 23 )$$

Here, when the diffraction vector V1 is represented by above Formula (14), the in-plane wavenumber vectors K1 to K4 after the diffraction vector V1 is added are represented by the following Formulas (24) to (27), respectively.

$$[ Formula 24 ]$$

$$K 1 = ( \frac{π}{a} + Vx , \frac{π}{a} + Vy ) \qquad ( 24 )$$

$$[ Formula 25 ]$$

$$K 2 = ( - \frac{π}{a} + Vx , \frac{π}{a} + Vy ) \qquad ( 25 )$$

$$[ Formula 26 ]$$

$$K 3 = ( - \frac{π}{a} + Vx , - \frac{π}{a} + Vy ) \qquad ( 26 )$$

$$[ Formula 27 ]$$

$$K 4 = ( \frac{π}{a} + Vx , - \frac{π}{a} + Vy ) \qquad ( 27 )$$

In Formulas (24) to (27), when considering that any of the in-plane wavenumber vectors K1 to K4 is contained in the region LL2, the relationship of the following Formula (28) holds. That is, by adding the diffraction vector V1 that satisfies Formula (28), any of the in-plane wavenumber vectors K1 to K4 excluding the wavenumber spread Δk is contained in the region LL2. Even in such a case, it is possible to output part of the +1-order light and the −1-order light without outputting the zero-order light.

$$[ Formula 28 ]$$

$${( \pm \frac{π}{a} + Vx )}^{2} + {( \pm \frac{π}{a} + Vy )}^{2} < {( \frac{2 π}{λ} - Δ k )}^{2} \qquad ( 28 )$$

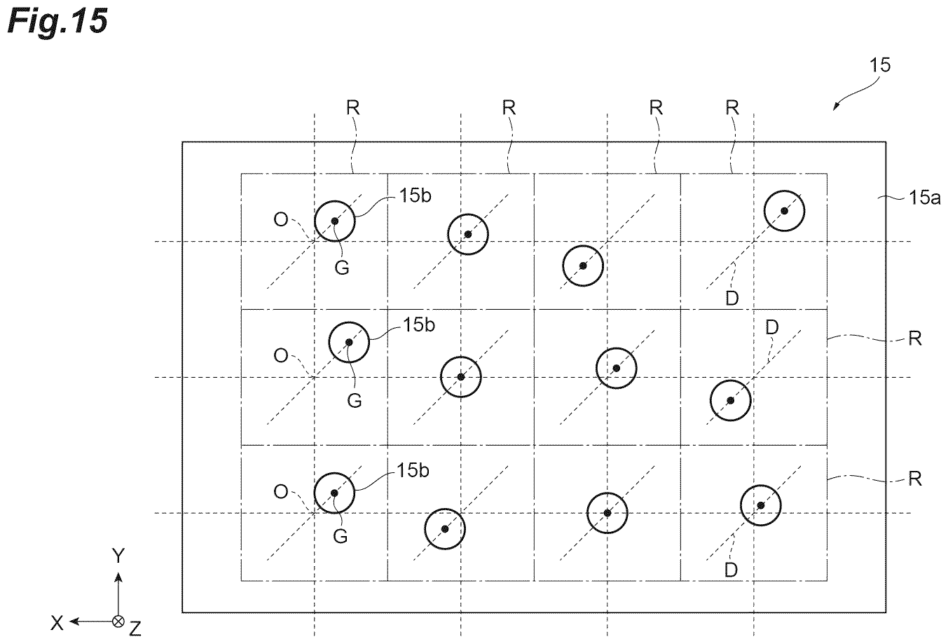

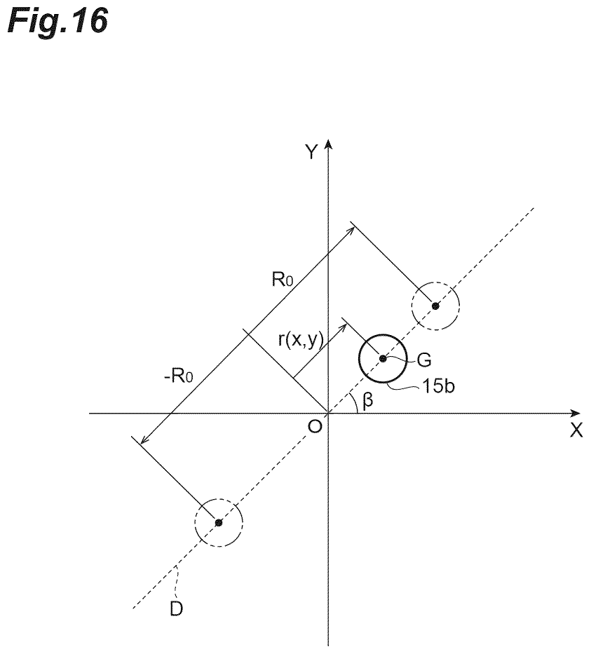

FIG. 15 is a plan view of another form of the phase modulation layer 15. FIG. 16 is a diagram showing arrangement of the modified refractive index regions 15b in the phase modulation layer 15 shown in FIG. 15. As shown in FIGS. 15 and 16, the centers of gravity G of the plurality of modified refractive index regions 15b of the phase modulation layer 15 may be arranged on a plurality of straight lines D, respectively. Each of the straight lines D is a straight line that passes through the lattice point O corresponding to each unit constituent region R and is inclined to each side of the square lattice. That is, the straight line D is a straight line inclined to both the X axis and the Y axis. The inclination angle of the straight line D with respect to one side of the square lattice, in other words, with respect to the X axis is β.

In this case, the inclination angle β is uniform within the phase modulation layer 15. The inclination angle β satisfies 0°<β<90°, and in one example, β=45°. Alternatively, the inclination angle β satisfies 180°<β<270°, and in one example, β=225°. When the inclination angle β satisfies 0°<β<90° or 180°<β<270°, the straight line D extends from the first quadrant to the third quadrant of the coordinate plane defined by the X and Y axes. The inclination angle β satisfies 90° <β<180°, and in one example, β=135°. Alternatively, the inclination angle β satisfies 270°<β<360°, and in one example, β=315°. When the inclination angle β satisfies 90°<β<180° or 270°<β<360°, the straight line D extends from the second quadrant to the fourth quadrant of the coordinate plane defined by the X and Y axes. In this way, the inclination angle β is an angle excluding 0°, 90°, 180°, and 270°.

Here, r(x, y) is the distance between the lattice point O and the center of gravity G. x is the position of the x-th lattice point on the X axis, and y is the position of the y-th lattice point on the Y axis. When the distance r(x, y) is a positive value, the center of gravity G is located in the first or second quadrant. When the distance r(x, y) is a negative value, the center of gravity G is located in the third or fourth quadrant. When the distance r(x, y) is zero, the lattice point O and the center of gravity G agree with each other. The inclination angle β is suitably 45°, 135°, 225°, and 275°. For these inclination angles, only two of four in-plane wavenumber vectors forming a standing wave at point M, for example, two of the in-plane wavenumber vectors (±π/a, ±π/a) are phase modulated, whereas the other two are not phase modulated. Therefore, stable standing waves can be formed.

The distance r(x, y) between the center of gravity G of each modified refractive index region and the lattice point O corresponding to each unit constituent region R is set individually for each modified refractive index region 15b according to the phase distribution φ(x, y) corresponding to the desired light output shape. The distances r(x, y) between the centers of gravity G of at least two modified refractive index regions 15b and the lattice point O differ from each other. In the present disclosure, such an arrangement form of the center of gravity G is referred to as a second arrangement form. The phase distribution φ(x, y) and the distribution of the distance r(x, y) have specific values for each position determined by the x and y values, but are not necessarily represented by a specific function. The distribution of the distance r(x, y) is determined by extracting the phase distribution φ(x, y) from the complex amplitude distribution obtained by performing inverse Fourier transform on the desired light output shape.

That is, when the phase φ(x, y) at some coordinates (x, y) is φ₀, the distance r(x, y) is set to 0. When the phase φ(x, y) is π+φ₀, the distance r(x, y) is set to the maximum value R₀. When the phase φ(x, y) is −π+φ₀, the distance r(x, y) is set to the minimum value −R₀. For an intermediate phase φ(x, y) therebetween, the distance r(x, y) is set such that r(x, y)={φ(x, y)−φ₀}×R₀/π. The initial phase φ₀ can be set arbitrarily.

When the lattice spacing of the virtual square lattice is a, the maximum value R₀ of r(x, y) is, for example, in the range of Formula (29) below. When obtaining the complex amplitude distribution from the desired optical image, reproducibility of the beam pattern can be improved by applying iterative algorithm such as the GS method commonly used for calculation for hologram generation.

$$[ Formula 29 ]$$

$$0 \leq {R}_{0} \leq \frac{a}{\sqrt{2}} \qquad ( 29 )$$

In this second arrangement form, by determining the distribution of the distance r(x, y) of the modified refractive index regions 15b of the phase modulation layer 15, the desired light emission shape can be obtained about the number and position of the focal points and the like. Under the first to fourth preconditions similar to the first arrangement form, the phase modulation layer 15 is configured to satisfy the following condition. That is, the corresponding modified refractive index regions 15b are arranged in the unit constituent region R(x, y) such that the distance r(x, y) from the lattice point O(x, y) to the center of gravity G of the corresponding modified refractive index region 15b satisfies the following relationship.

r(x,y)=C×(q)(x,y)−φ₀)

C: constant of proportionality, for example, R₀/π

φ₀: arbitrary constant, for example, 0

To obtain the desired light emission shape, it is preferable to perform inverse Fourier transform on the light emission shape and give the distribution of the distance r(x, y) corresponding to the phase φ(x, y) of the complex amplitude to the plurality of modified refractive index regions 15b. The phase φ(x, y) and the distance r(x, y) may be proportional to each other.

In this second arrangement form as well, as in the first arrangement form described above, the lattice spacing a of the virtual square lattice and the light emission wavelength λ of the active layer 12 satisfy the condition for M-point oscillation. Furthermore, when considering a reciprocal lattice space in the phase modulation layer 15, the magnitude of at least one of the four-direction in-plane wavenumber vectors K1 to K4 each including the wavenumber spread due to the distribution of the distance r(x, y) is less than 2π/λ, that is, the light line LL.

In the second arrangement form as well, by applying the following ingenious way to the phase modulation layer 15 in the light-emitting device that oscillates at the M point, part of the +1-order light and the −1-order light is output without output of the zero-order light into the light line LL. Specifically, as shown in FIG. 11, the diffraction vector V1 having a certain magnitude and direction is added to the in-plane wavenumber vectors K1 to K4. With this addition, the magnitude of at least one of the in-plane wavenumber vectors K1 to K4 is made smaller than 2π/λ. That is, at least one of the in-plane wavenumber vectors K1 to K4 after the diffraction vector V1 is added is contained in the light line LL that is a circular region with a radius of 2π/λ. By adding the diffraction vector V1 that satisfies Formula (19) described above, any of the in-plane wavenumber vectors K1 to K4 is contained in the light line LL, and part of the +1-order light and the −1-order light is output.

Alternatively, as shown in FIG. 14, the diffraction vector V1 may be added to the four-direction in-plane wavenumber vectors K1 to K4 excluding the wavenumber spread Δk, that is, the four-direction in-plane wavenumber vectors in the square lattice PCSEL of M-point oscillation. With this addition, the magnitude of at least one of the four-direction in-plane wavenumber vectors K1 to K4 may be smaller than the value {(2π/λ)−Δk} obtained by subtracting the wavenumber spread Δk from 2π/λ. That is, by adding the diffraction vector V1 that satisfies Formula (28) described above, any of the in-plane wavenumber vectors K1 to K4 is contained in the region LL2, and part of the +1-order light and the −1-order light is output.

Here, the design of the phase modulation layer 15 for emitting light while focusing the light from the light-emitting device 1 will be described in detail.

[Single Focal Point Type (A)]

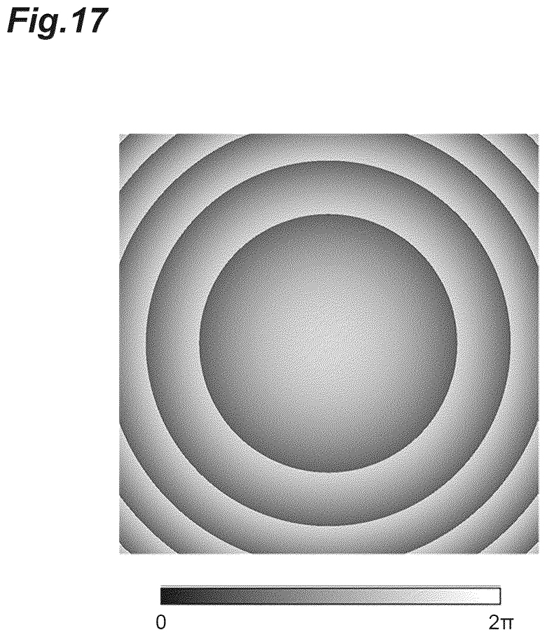

To begin with, the design of the phase modulation layer 15 for forming a single focal point U by the light-emitting device 1 itself will be described. In this case, as the phase distribution φ₁(x, y) for obtaining the desired light output shape, a phase distribution including a lens element for focusing light output, that is, lens phase distribution φ_{L}(x, y) is set. FIG. 17 is a diagram showing an example of the lens phase distribution φ_{L}(x, y). In this figure, the magnitude of the phase is represented by a shade of color. The magnitude of the phase is closer to 0 (rad) as the color is darker, and is closer to 2π (rad) as the color is lighter. In this example, the phase decreases as the distance from the center of the phase modulation layer 15 increases. This lens phase distribution φ_{L}(x, y) can act as a convex lens element for the light output. This lens phase distribution φ_{L}(x, y) is represented by Formula (30). Here, λ is the wavelength in the medium in the phase modulation layer 15, (x, y) is the in-plane lattice point position, and f is the focal length. The sign of the focal length f may be either + or −. When the sign of the focal length f is +, the lens is a concave lens, and when the sign is −, the lens is a convex lens.

[Formula 30]

ϕ_{L}(x,y)=±(2π/λ)(\sqrt{x²+y²+f²}−f) (30)

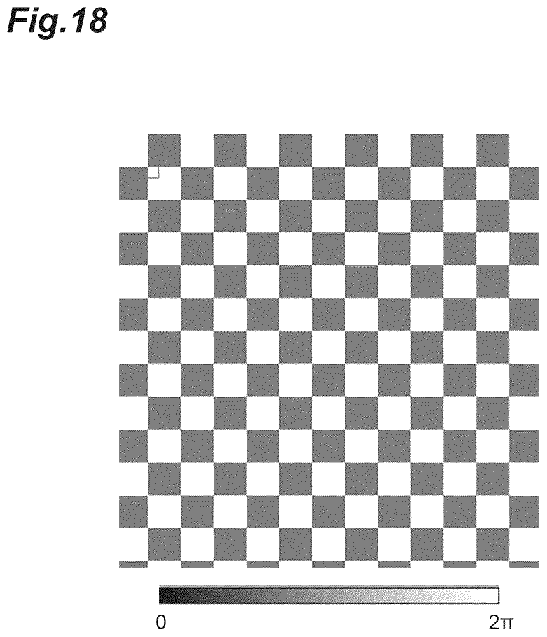

FIG. 18 is a diagram showing the partially enlarged lens phase distribution φ_{L}(x, y). Looking locally at this lens phase distribution φ_{L}(x, y), as in FIG. 13, at a glance, the first phase value and the second phase value different from the first phase value are arranged in a checkered pattern. For example, such a lens phase distribution φ_{L}(x, y) allows the diffraction vector V1 to be added to the in-plane wavenumber vectors K1 to K4. The phase value of each portion of the phase modulation layer 15 is obtained as the sum of average values of the first and second phase values contained in each portion.

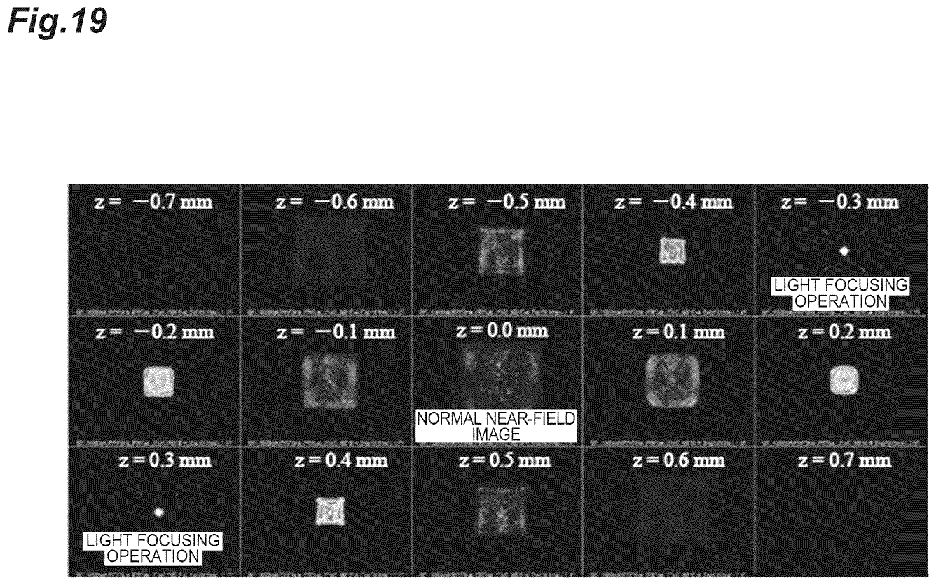

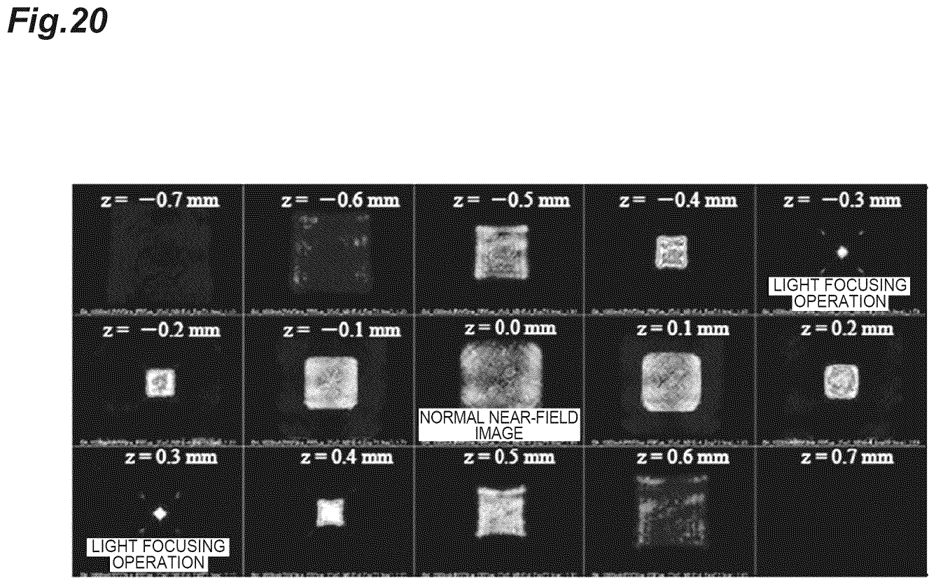

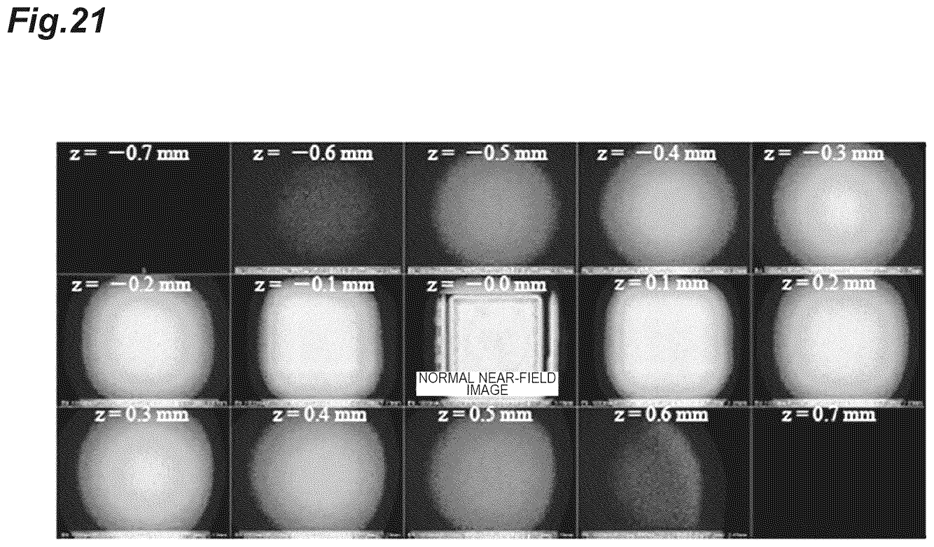

FIGS. 19 and 20 are diagrams showing results of an experiment. In this experiment, the light-emitting device 1 of the present embodiment was prototyped and the near-field image was captured while moving an objective lens in the Z direction. The movement interval of the objective lens was set to 100 μm, and the Z-axis coordinate of the light emission surface was set to z=0 mm. The light emission wavelength λ of the prototyped light-emitting device 1 was set to 940 nm, the lattice spacing a was set to 202 nm, the length r of the vector connecting the lattice point O to the center of gravity G was set to 0.08a, and the focal length f was set to 0.32 mm FIG. 19 shows a case where the lens phase distribution φ_{L}(x, y) is a convex lens. FIG. 20 shows a case where the lens phase distribution φ_{L}(x, y) is a concave lens. FIG. 21 is a diagram showing results of producing a normal light-emitting device (LED) without the phase modulation layer 15 and capturing the near-field image in the same manner for comparison. In FIGS. 19 to 21, light intensity is represented by a shade of color, with lighter colors indicating greater light intensity.

With reference to FIGS. 19 and 20, it can be seen that in the light-emitting device 1 of the present embodiment, the light output converges at a position 0.3 mm from the light emission surface. As shown in FIG. 21, in the normal light-emitting device, the near-field image becomes clear at the light emission surface (z=0 mm), and the near-field image becomes unclear away from the light emission surface. In this way, the light-emitting device 1 of the present embodiment can emit light while focusing the light.

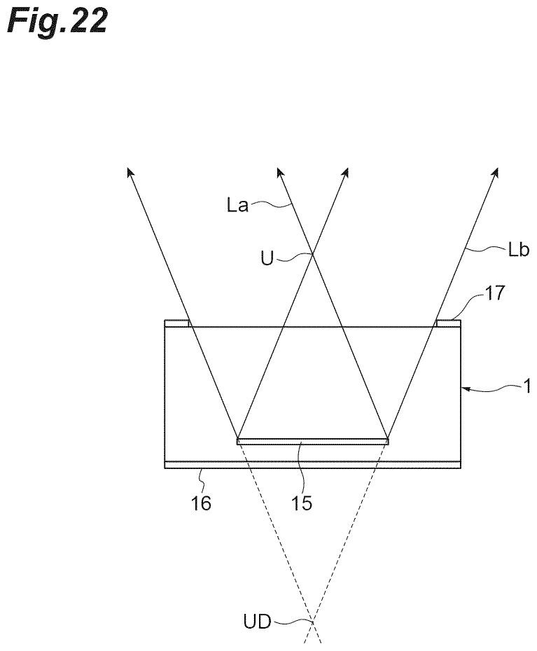

In this experiment, the light output converged at a position −0.3 mm from the light emission surface as well. The position −0.3 mm from the light emission surface is opposite the light emission surface of the light-emitting device 1. The reason is considered as follows. That is, as shown in FIG. 22, the +1-order light La and the −1-order light Lb are emitted in mutually symmetrical directions from the phase modulation layer 15 of the light-emitting device 1. When the lens phase distribution φ_{L}(x, y) is a convex lens, the +1-order light La converges at the focal point U at a certain distance from the phase modulation layer 15, and the −1-order light Lb as a virtual image converges at the focal point UD at a certain distance on the opposite side of the phase modulation layer 15. With reference to FIG. 19, the +1-order light La converges at the focal point U 0.3 mm from the phase modulation layer 15, and the −1-order light Lb as a virtual image converges at the focal point UD −0.3 mm from the phase modulation layer 15. Conversely, when the lens phase distribution φ_{L}(x, y) is a concave lens, the −1-order light Lb converges at the focal point U at a certain distance from the phase modulation layer 15, and the +1-order light La converges at the focal point UD at a certain distance on the opposite side of the phase modulation layer 15. With reference to FIG. 20, the −1-order light Lb converges at the focal point U 0.3 mm from the phase modulation layer 15, and the +1-order light La converges at the focal point UD −0.3 mm from the phase modulation layer 15.

[Single Focal Point Type (B)]

Next, one of the designs of the phase modulation layer 15 for forming the single focal point U by the single light-emitting device 1 itself will be described. As described above, according to the checkered phase distribution φ₂(x, y) shown in FIG. 13, since the diffraction vector V1 is V1=(±π/a, ±π/a), the diffraction vector V1 and any one of the in-plane wavenumber vectors K1 to K4 shown in FIG. 10 exactly cancel each other. Therefore, any one of the in-plane wavenumber vectors K1 to K4 becomes a zero vector, the axis of symmetry of the +1-order light and the −1-order light agrees with the Z direction, that is, the direction perpendicular to the in-plane direction of the phase modulation layer 15.

In one design of single focal point type, the lengths of the in-plane wavenumber vectors K1 to K4 are all made greater than zero by changing the diffraction vector V1 described above. That is, the in-plane wavenumber vectors K1 to K4 are non-zero vectors. This causes the axis of symmetry of the +1-order light and the −1-order light to be inclined from the Z direction. In other words, the central position of the optical image output from the light-emitting device 1 is spaced apart from an axis passing through the center of the light emission surface of the light-emitting device 1 and extending in the Z direction. Such a diffraction vector V1 is obtained by adding a non-zero vector (dVx, dVy) to the diffraction vector V1=(±π/a, ±π/a). That is, the diffraction vector V1 is V1=±(π/a)(1+dVx, 1+dVy). In this case, the phase distribution φ(x, y) including the lens phase distribution φ_{L}(x, y) is represented as follows.

[Formula 31]

ϕ(x,y)=±(π/a)((1+dVₓ)x+(1+dV_{y})y)+ϕ_{L}(x,y) (31)

Components of the phase distribution corresponding to the non-zero vector (dVx, dVy) constitute an element for focusing the light output to one focal point U in the phase distribution φ(x, y) together with the lens phase distribution φ_{L}(x, y). Even if the axis of symmetry of the +1-order light and the −1-order light is inclined from the Z direction, the +1-order light and the −1-order light both form the focal point U at the same position on the light emission surface side of the light-emitting device 1. Therefore, this design can suitably form one focal point U.

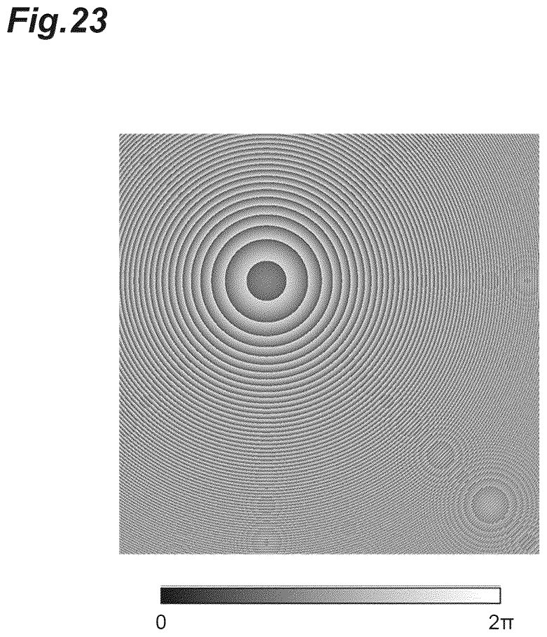

FIG. 23 is a diagram showing an example of the phase distribution φ(x, y) including the lens phase distribution φ_{L}(x, y) and the components corresponding to the non-zero vector (dVx, dVy). In this figure, the magnitude of the phase is represented by a shade of color. The magnitude of the phase is closer to 0 (rad) as the color is darker, and is closer to 2π (rad) as the color is lighter.

[Multiple Focal Points Type]

Subsequently, one of the designs of the phase modulation layer 15 for forming the plurality of focal points U by the single light-emitting device 1 itself will be described. In this design, the hologram phase distribution φ_{H}(x, y) for emitting the light output Lout toward at least two points, and the lens phase distribution φ_{L}(x, y) for focusing the light output Lout are synthesized. Then, the phase distribution obtained by the synthesis is included in the phase distribution φ₁(x, y) as an element for focusing the light output to at least two focal points U. After that, the sum of the phase distribution φ₁(x, y) and the phase distribution φ₂(x, y) for the diffraction vector V1 is calculated to obtain the final phase distribution φ(x, y). The phase distribution φ₁(x, y) may include only the phase distribution obtained by synthesizing the hologram phase distribution φ_{H}(x, y) and the lens phase distribution φ_{L}(x, y). Note that the hologram phase distribution φ_{H}(x, y) corresponds to a first phase distribution in the present disclosure, and the lens phase distribution φ_{L}(x, y) corresponds to a second phase distribution in the present disclosure.

The hologram phase distribution φ_{H}(x, y) forms the at least two points at positions away from the axis passing through the center of the light emission surface of the light-emitting device 1 and extending in the Z direction. In other words, the hologram phase distribution φ_{H}(x, y) is a phase distribution in which the in-plane wavenumber vectors K1 to K4 are non-zero vectors, and a hologram for emitting light toward two or more points different from each other is formed.

Consider a case where at least two focal points U are located on the same imaginary plane perpendicular to the z axis. In that case, as one example of a method for synthesizing the hologram phase distribution φ_{H}(x, y) and the lens phase distribution φ_{L}(x, y), there is a method for obtaining the sum φ_{H}(x, y)+φ_{L}(x, y) of a phase value of the hologram phase distribution φ_{H}(x, y) and a phase value of the lens phase distribution φ_{L}(x, y) at each z coordinate. Consider a case where at least two focal points U are separately located on a plurality of imaginary planes that are each perpendicular to the z axis and have different z coordinates. In that case, examples of the method for synthesizing the hologram phase distribution φ_{H}(x, y) and the lens phase distribution φ_{L}(x, y) include the following methods. In each of the following methods, to begin with, synthetic phase distributions φ_{S}_{₁}(x, y) to φ_{S}_{ₙ}(x, y), which are the sum φ_{H}(x, y)+φ_{L}(x, y) of the phase value of the hologram phase distribution φ_{H}(x, y) and the phase value of the lens phase distribution φ_{L}(x, y), are calculated for each imaginary plane. n is the number of imaginary planes. After that, the synthetic phase distributions φ_{S}_{₁}(x, y) to φ_{S}_{ₙ}(x, y) are synthesized with each other. The synthesized phase distribution is included in the phase distribution φ₁(x, y) as an element for focusing the light output to at least two focal points U.

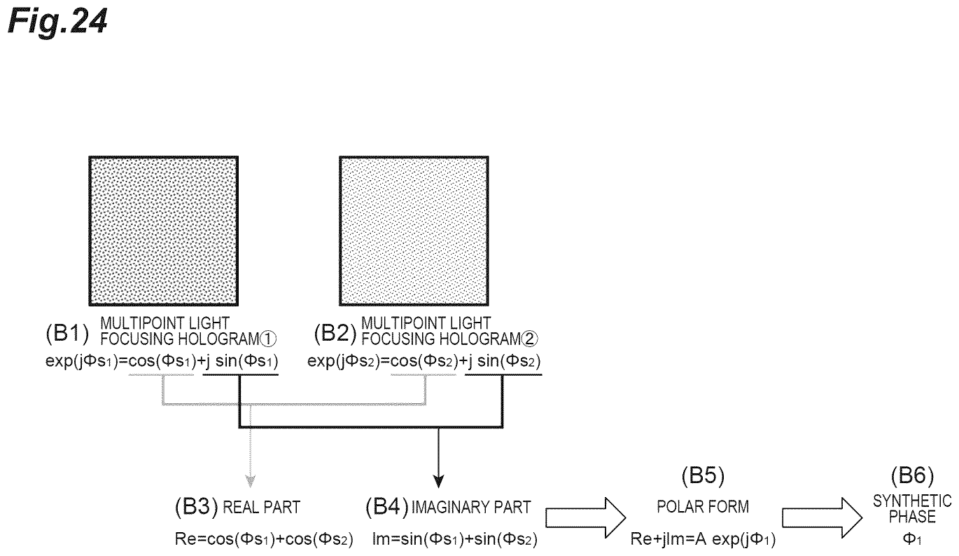

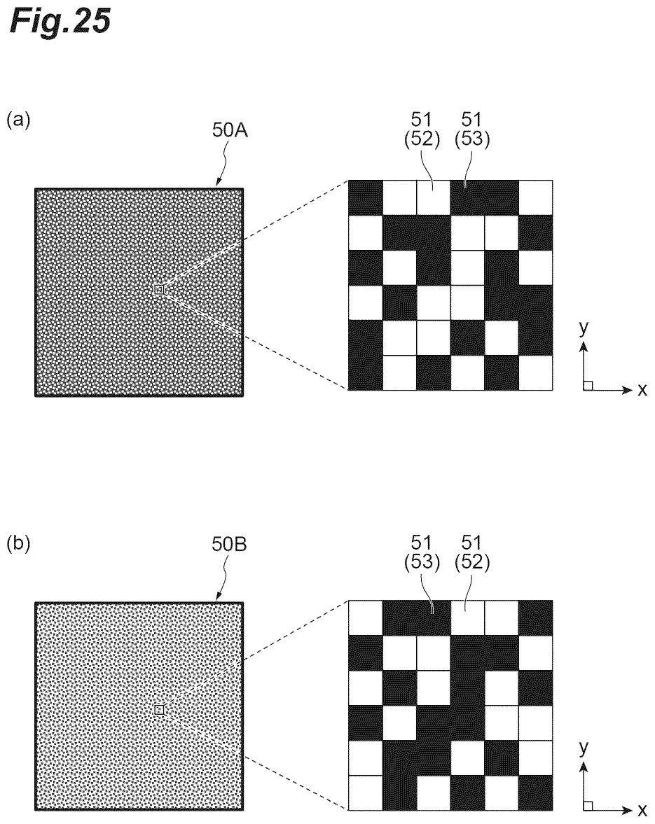

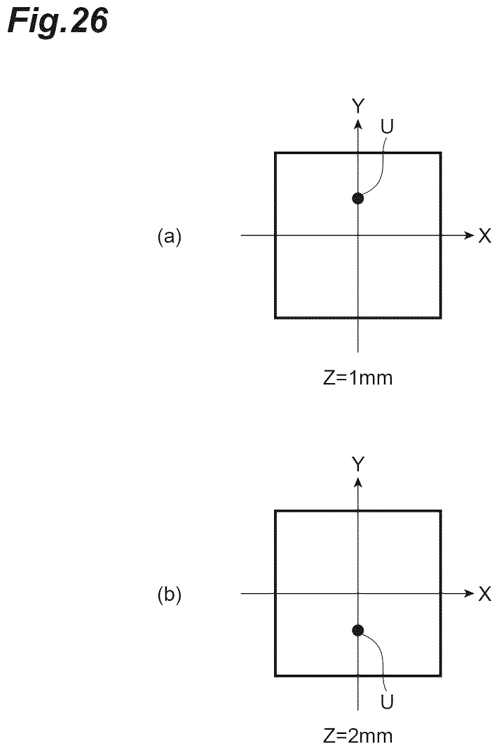

One is a method for dividing each of the synthetic phase distributions φ_{S}_{₁}(x, y) to φ_{S}_{ₙ}(x, y) into a real part and an imaginary part, and synthesizing the phase in each of the real part and the imaginary part. This method is hereinafter referred to as a first method. FIG. 24 is a conceptual diagram of this first method. Here, FIG. 24 shows the case of n=2. To begin with, as shown below, each of the synthetic phase distributions φ_{S}_{₁}(x, y) to φ_{S}_{ₙ}(x, y) is divided into a real part and an imaginary part (processing B1 and B2 in the figure).

$$\begin{matrix}exp ( j \cdot φ {s}_{1} ) = cos ( φ {s}_{1} ) + j \cdot sin ( φ {s}_{1} ) \\ exp ( j \cdot φ {s}_{2} ) = cos ( φ {s}_{2} ) + j \cdot sin ( φ {s}_{2} ) \\ \cdot \\ \cdot \\ \cdot \\ exp ( j \cdot φ {s}_{n} ) = cos ( φ {s}_{n} ) + j \cdot sin ( φ {s}_{n} )\end{matrix}$$

Next, the real parts of the synthetic phase distributions φ_{S}_{₁}(x, y) to φ_{S}_{ₙ}(x, y) are added to each other as follows, and the imaginary parts are added to each other (processing B3 and B4 in the figure).

Real part Re=cos(φ_{S}_{ᵢ})+cos(φ_{S}_{₂})+ . . . +cos(φ_{S}_{ₙ})

Imaginary part Im=sin(φ_{S}_{ᵢ})+sin(φ_{S}_{₂})+ . . . +sin(φ_{S}_{ₙ})

Then, the real part Re and the imaginary part Im are described in the polar form as follows (processing B5 in the figure).

Re+j·Im=A·exp(j·φ₁)

Here, A is the amplitude and φ₁ is the argument.

By the above calculation, the synthetic phase φ₁ at each coordinate (x, y), that is, the phase distribution φ₁(x, y) for focusing light to at least two focal points U is obtained (processing B6 in the figure).

Another method is to use the average value of the synthetic phase distributions φ_{S}_{ᵢ}(x, y) to φ_{S}_{ₙ}(x, y) as the phase distribution φ₁(x, y). This method is hereinafter referred to as a second method. By this second method, the phase distribution φ₁(x, y) at the coordinate (x, y) is calculated as (φ_{S}_{ᵢ}+φ_{S}_{₂}+ . . . +φ_{S}_{ₙ})/n.

Still another method is to two-dimensionally and randomly select phase values from respective synthetic phase distributions φ_{S}_{ᵢ}(x, y) to φ_{S}_{ₙ}(x, y) and superimpose the selected phase values. This method is hereinafter referred to as a third method. By this third method, at each coordinate (x, y), by selecting phase values from only one of the synthetic phase distributions φ_{S}_{ᵢ}(x, y) to φ_{S}_{ₙ}(x, y), the phase values of two or more synthetic phase distributions φ_{S}_{ᵢ}(x, y) to φ_{S}_{ₙ}(x, y) are made to not overlap each other. FIG. 25 is a diagram showing an example of random patterns used for this third method. Here, in FIG. 25, the case of n=2 is assumed. Part (a) of FIG. 25 shows a random pattern 50A applied to the synthetic phase distribution φ_{S}_{ᵢ}(x, y). Part (b) of FIG. 25 shows a random pattern 50B applied to the synthetic phase distribution φ_{S}_{₂}(x, y). These random patterns 50A and 50B each have a plurality of regions 51 arranged in a two-dimensional form along the x direction and the y direction. These regions 51 correspond one-to-one to respective phase values of the phase distribution. In the figure, the plurality of regions 51 is colored in black and white. Here, the white region is a region 52 where the phase value is selected, and the black region is a region 53 where the phase value is not selected. (Hereinafter, the region 52 will be referred to as a selected region, and the region 53 will be referred to as a non-selected region. That is, the phase value at coordinates (x, y) corresponding to the selected region 52 of the random pattern 50A is selected from the synthetic phase distribution φ_{S}_{₁}(x, y). The phase value at coordinates (x, y) corresponding to the selected region 52 of the random pattern 50B is selected from the synthetic phase distribution φ_{S}_{₂}(x, y). Comparing the random pattern 50A and the random pattern 50B, the selected region 52 of the random pattern 50A and the selected region 52 of the random pattern 50B are distributed complementarily. That is, the selected region 52 in the random pattern 50A is always the non-selected region 53 in the random pattern 50B. The non-selected region 53 in the random pattern 50A is always the selected region 52 in the random pattern 50B. The selected region 52 is two-dimensionally and randomly distributed in the xy plane. The number of selected regions 52 in the random pattern 50A may be equal to or slightly different from the number of selected regions 52 in the random pattern 50B. In other words, the number of phase values selected from the synthetic phase distribution φ_{S}_{₁}(x, y) may be equal to or slightly different from the number of phase values selected from the synthetic phase distribution φ_{S}_{₂}(x, y).

One example of the method for creating the random patterns 50A and 50B described above will be given. There are methods such as, for example, assigning a value to each region from a random number from 0 to 1, defining the region whose value is 0 or more and less than ½ as the selected region 52 of the random pattern 50A, and defining the region of ½ or more and 1 or less as the selected region 52 of the random pattern 50B. For creating the random number distribution, for example, the Rand function of MATLAB (registered trademark), which is numerical calculation software, can be used.

The case of n=2 is assumed in FIG. 25, but n may be 3 or more. For n=3, the selected region 52 of the random pattern corresponding to the synthetic phase distribution φ_{S}_{₁}(x, y), the selected region 52 of the random pattern corresponding to the synthetic phase distribution φ_{S}_{₂}(x, y), and the selected region 52 of the random pattern corresponding to the synthetic phase distribution φ_{S}_{₃}(x, y) are distributed complementarily. That is, the selected region 52 in the random pattern corresponding to the synthetic phase distribution φ_{S}_{₁}(x, y) is always the non-selected region 53 in each random pattern corresponding to the other synthetic phase distributions φ_{S}_{₂}(x, y) and φ_{S}_{₃}(x, y). The selected region 52 in the random pattern corresponding to the synthetic phase distribution φ_{S}_{₂}(x, y) is always the non-selected region 53 in each random pattern corresponding to the other synthetic phase distributions φ_{S}_{₁}(x, y) and φ_{S}_{₃}(x, y). The selected region 52 in the random pattern corresponding to the synthetic phase distribution φ_{S}_{₃}(x, y) is always the non-selected region 53 in each random pattern corresponding to the other synthetic phase distributions φ_{S}_{₁}(x, y) and φ_{S}_{₂}(x, y). One example of the method for creating such a random pattern will be given. There are methods such as, for example, assigning a value to each region from a random number from 0 to 1, defining the region whose value is 0 or more and less than ⅓ as the selected region 52 of the random pattern corresponding to the synthetic phase distribution φ_{S}_{₁}(x, y), defining the region whose value is ⅓ or more and less than ⅔ as the selected region 52 of the random pattern corresponding to the synthetic phase distribution φ_{S}_{₂}(x, y), and defining the region whose value is ⅔ or more and equal to or less than 1 as the selected region 52 of the random pattern corresponding to the synthetic phase distribution φ_{S}_{₃}(x, y). When n is 4 or more as well, the random pattern can be created by a method similar to the above method.

By each of the above methods, the +1-order light can be emitted toward at least two points according to the hologram phase distribution φ_{H}(x, y). Therefore, at least two focal points U can be formed by using only the +1-order light.

Results of the experiment are shown in which the two points light focusing type light-emitting device 1 is prototyped and the near-field image is captured while moving the objective lens in the Z direction. FIG. 26 is a diagram showing the location of the focal points U. In this experiment, as shown in part (a) of FIG. 26, one focal point U was formed at a position a predetermined distance in the +Y direction away from an axis passing through the center of the light emission surface of the light-emitting device 1 and extending in the Z direction. The distance z in the Z direction from the light emission surface to the focal point U is 1 mm. At the same time, as shown in part (b) of FIG. 26, the other focal point U was formed at a position a predetermined distance in the −Y direction away from an axis passing through the center of the light emission surface of the light-emitting device 1 and extending in the Z direction. The distance z in the Z direction from the light emission surface to the focal point U is 2 mm. In this experiment, the movement interval of the Objective lens was set to 100 μm to 1000 μm, and the Z-axis coordinate of the light emission surface was set to z=0 mm. The light emission wavelength λ, the lattice spacing a, and the length r of the vector connecting the lattice point O to the center of gravity G of the prototype light-emitting device 1 are as in FIGS. 19 to 21.

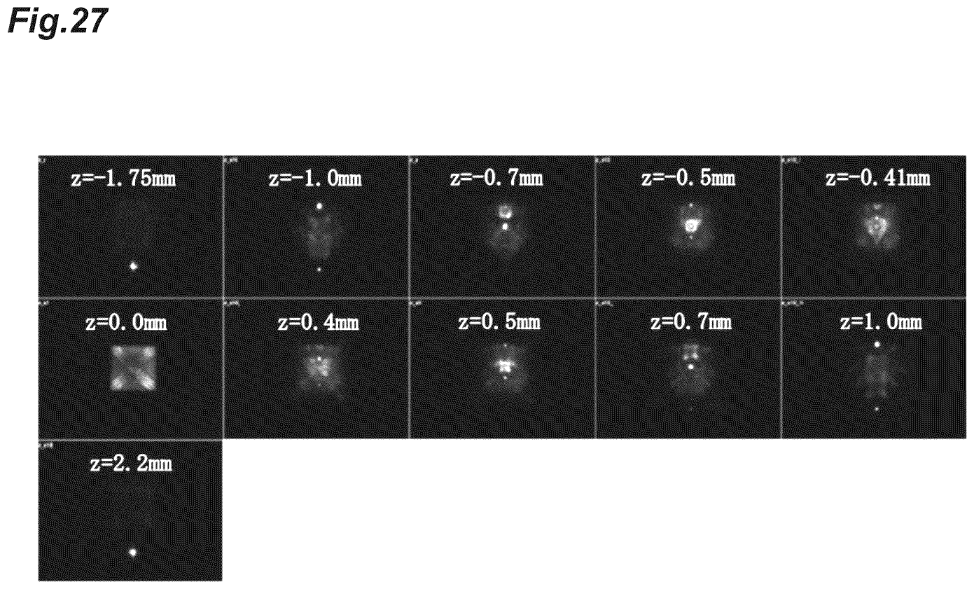

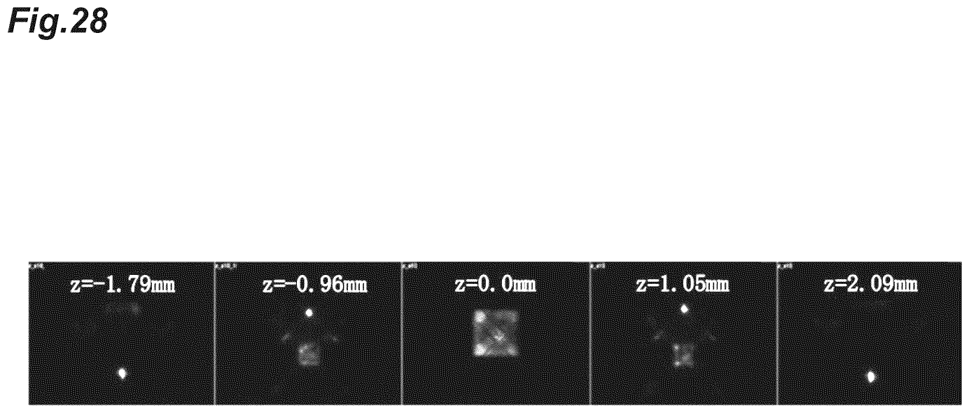

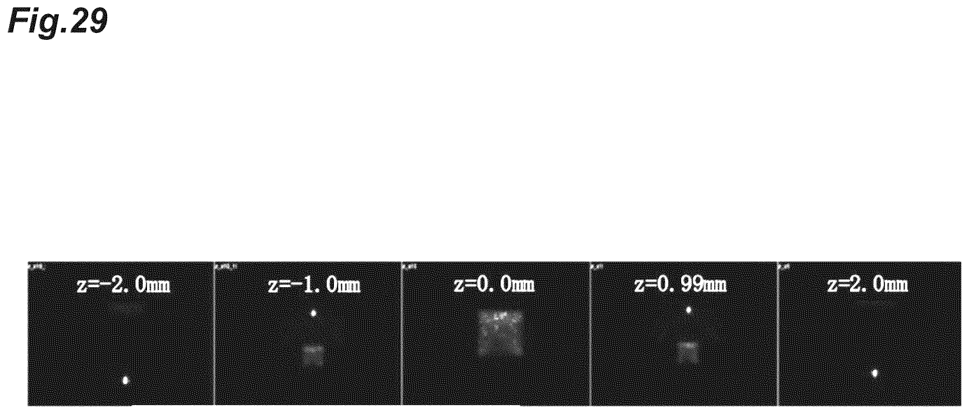

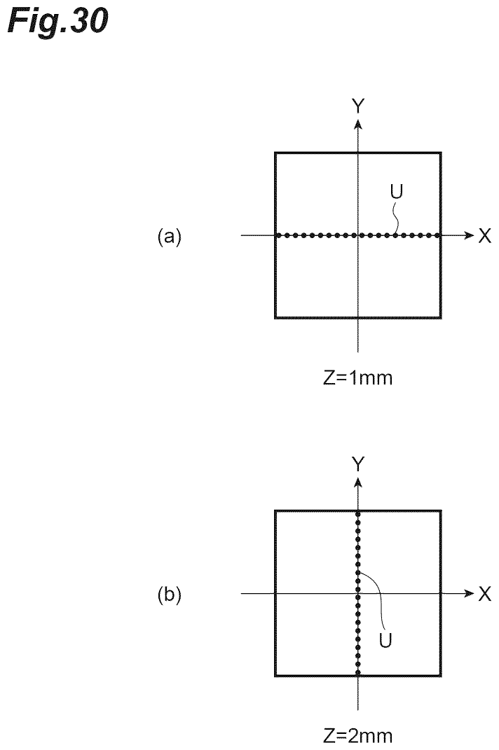

FIGS. 27 to 29 show near-field images of the light-emitting device 1 produced in the experiment. FIG. 27 shows the near-field image of the light-emitting device 1 produced by the second method described above. FIG. 28 shows the near-field image of the light-emitting device 1 produced by the first method described above (see FIG. 24). FIG. 29 shows the near-field image of the light-emitting device 1 produced by the third method described above. In FIGS. 27 to 29, light intensity is represented by a shade of color, with lighter colors indicating greater light intensity.

With reference to FIGS. 27 to 29, in both methods, it can be seen that the focal point U shown in FIG. 26 appears at each position of z=1 mm and z=2 mm. However, with reference to FIG. 27, substantially square noise is identified near the center. The magnitude of the substantially square noise does not change significantly even if the defocus distance z is changed within the range shown in FIG. 27. Therefore, it is considered to be a defocused image, which is a near-field image the light focusing action of the lens phase does not reach. The spread of the defocused image shown in FIG. 27 is smaller than the spread of the defocused image of the light-emitting element (LED) shown in FIG. 21. This is caused by laser oscillation in a relatively large area with respect to the wavelength. Therefore, in the defocused image shown in FIG. 27, there is little diffraction spread, and sharp bright spots are seen in the direction perpendicular to the plane. Therefore, the substantially square noise is considered to be the light produced by the in-plane resonant standing wave diffracting in the direction perpendicular to the plane by the action of the diffraction vector V1, that is, a light component that has not undergone a phase modulation action by the synthetic phase of the hologram phase and the lens phase. Therefore, it is more preferable to produce the light-emitting device 1 by either the first method or the third method.

Next, results of the experiment are shown in which another multiple light focusing type light-emitting device 1 is prototyped and the near-field image is captured while moving the objective lens in the Z direction. FIG. 30 is a diagram showing the location of the focal points U. In this experiment, as shown in part (a) of FIG. 30, many focal points U were arranged along the X direction across an axis passing through the center of the light emission surface of the light-emitting device 1 and extending in the Z direction. The distance z in the Z direction from the light emission surface to these focal points U is 1 mm. At the same time, as shown in part (b) of FIG. 30, many other focal points U were arranged along the Y direction across the axis passing through the center of the light emission surface of the light-emitting device 1 and extending in the Z direction. The distance z in the Z direction from the light emission surface to these focal points U is 2 mm. In this experiment, the movement interval of the objective lens was set to 250 μm, and the Z-axis coordinate of the light emission surface was set to z=0 mm. The light emission wavelength λ, the lattice spacing a, and the length r of the vector connecting the lattice point O to the center of gravity G of the prototype light-emitting device 1 are as in FIGS. 19 to 21.

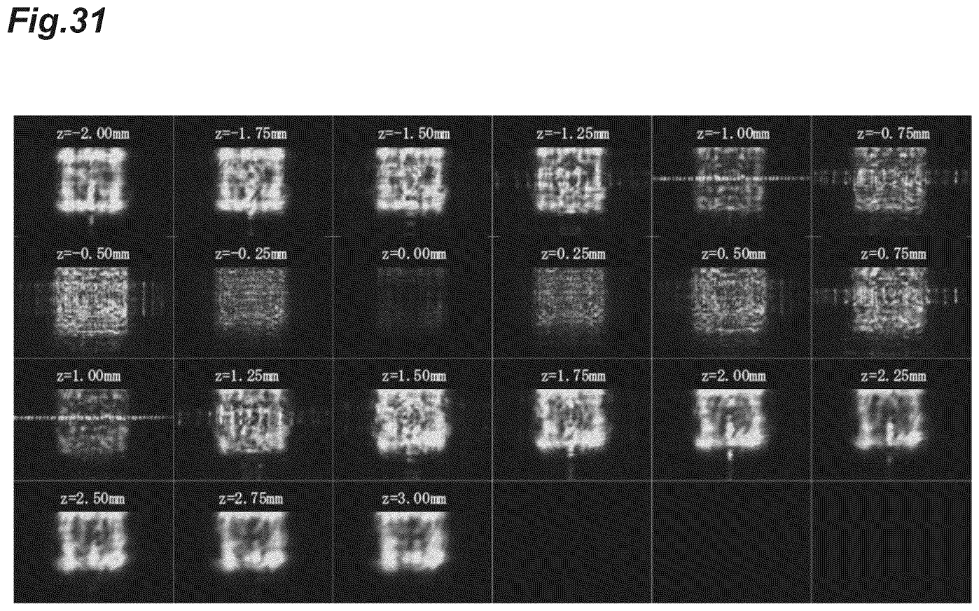

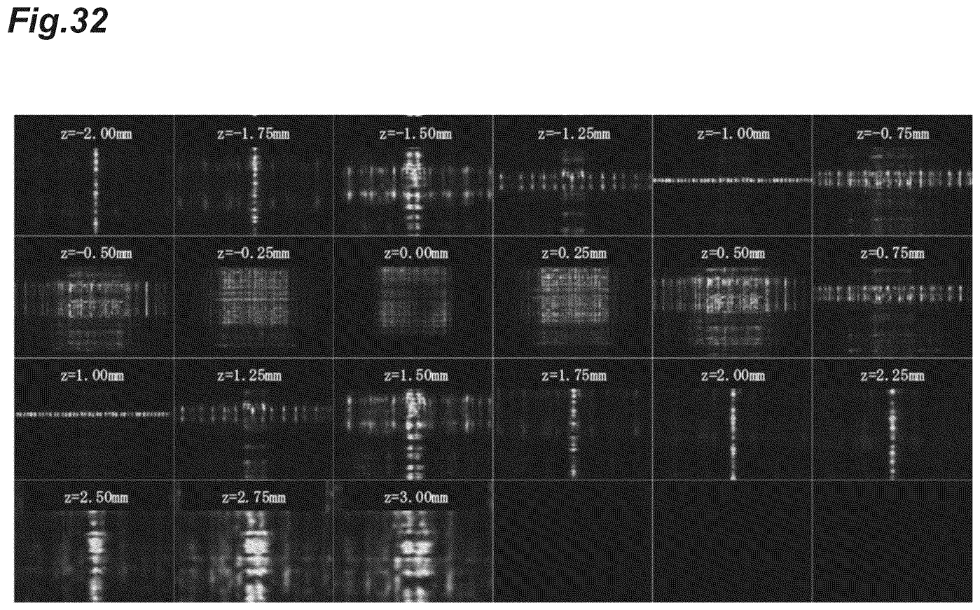

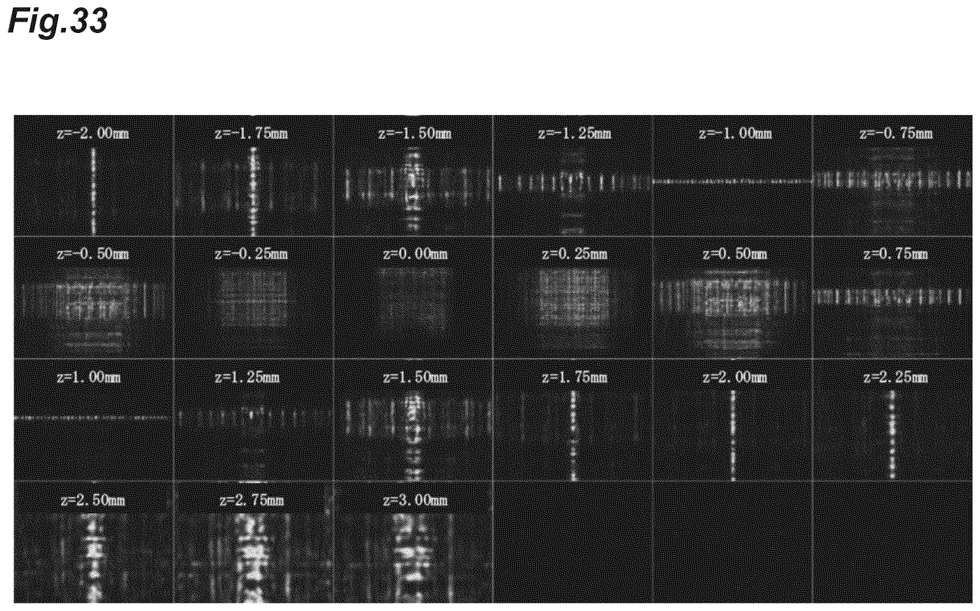

FIGS. 31 to 33 show near-field images of the light-emitting device 1 produced in the experiment. FIG. 31 shows the near-field image of the light-emitting device 1 produced by the second method described above. FIG. 32 shows the near-field image of the light-emitting device 1 produced by the first method described above (see FIG. 24). FIG. 33 shows the near-field image of the light-emitting device 1 produced by the third method described above. In FIGS. 31 to 33 as well, light intensity is represented by a shade of color, with lighter colors indicating greater light intensity.

With reference to FIGS. 31 to 33, in both methods, it can be seen that the focal points U shown in FIG. 30 appear at each position of z=1 mm and z=2 mm. However, with reference to FIG. 31, substantially square noise is identified near the center of the image. It is considered that this substantially square noise is caused by the same action as the substantially square noise shown in FIG. 27 described above. Therefore, it is more preferable to produce the light-emitting device 1 by either the first method or the third method.

In each of the above experiments as well, as in FIGS. 19 to 21 described above, the focal points appear at positions −1.0 mm and −2.0 mm from the light emission surface. The reason is that, while the +1-order light (or the −1-order light) as a real image converges in the region where z>0, the −1-order light (or the +1-order light) as a virtual image converges in the region where z<0.

Effects obtained by the light-emitting device 1 of the present embodiment described above will be described. In this light-emitting device 1, the center of gravity G of each modified refractive index region 15b is arranged away from the corresponding lattice point O of the virtual square lattice, and has an individual rotation angle α around the lattice point O according to the predetermined phase distribution φ(x, y). Alternatively, the center of gravity G of each modified refractive index region 15b is arranged on a straight line D passing through the lattice point O of the virtual square lattice and inclined to the square lattice, and the distance r between the center of gravity G of each modified refractive index region 15b and the lattice point O corresponding to each modified refractive index region 15b is set individually according to the predetermined phase distribution φ(x, y). With such a structure, it is possible to generate an arbitrarily shaped optical image as an S-iPM laser.

In addition, in this light-emitting device 1, the lattice spacing a of the square lattice and the light emission wavelength λ of the active layer 12 satisfy the condition for M-point oscillation. As described above, normally, in the standing wave state of M-point oscillation, light propagating in the phase modulation layer 15 undergoes total reflection. Therefore, output of both the signal light and zero-order light is suppressed. Here, the signal light is, for example, one or both of the +1-order light and the −1-order light. However, in this light-emitting device 1, on the reciprocal lattice space of the phase modulation layer 15, the standing wave undergoes phase modulation by the phase distribution φ(x, y), and forms four-direction in-plane wavenumber vectors K1 to K4 each including the wavenumber spread corresponding to the angular spread of the light output. At least one of these in-plane wavenumber vectors K1 to K4 has a magnitude smaller than 2π/λ, that is, the light line LL. In the S-iPM laser, such adjustment of the in-plane wavenumber vectors K1 to K4 is possible by applying an ingenious way to the arrangement of each modified refractive index region 15b. When the magnitude of at least one in-plane wavenumber vector is less than 2λ/λ, the in-plane wavenumber vector has a component in the thickness direction of the phase modulation layer 15 or the Z direction, and does not produce total reflection at the interface with air. As a result, part of the signal light is output from the phase modulation layer 15. However, if the condition for M-point oscillation is satisfied, the zero-order light is totally reflected at the interface with air and is not output from the phase modulation layer 15 into the light line LL. That is, the light-emitting device 1 of the present embodiment can remove the zero-order light contained in the output of the S-iPM laser from within the light line LL and can output only the signal light.

In addition, in the light-emitting device 1, the phase distribution φ(x, y) includes the element for focusing the light output Lout. This allows the light-emitting device 1 to output light while focusing the light. In addition, as described above, in the light-emitting device 1, since the output of zero-order light that does not contribute to light focusing is suppressed, only the signal light that can contribute to light focusing can be output. In this way, the light-emitting device 1, which can focus light by the light-emitting device 1 itself, can remove optical components for light focusing and miniaturize the light source device.

The element for focusing the light output Lout contained in the phase distribution φ(x, y) may be an element for focusing the light output Lout to at least two focal points U. As described above, by appropriately designing the element for focusing the light contained in the phase distribution φ(x, y), the light-emitting device 1 can also focus the light output Lout from one light-emitting device 1 to at least two focal points U. Therefore, at least two optical components for focusing light can be removed, and the light source device can be further miniaturized.

The element for focusing the light output Lout contained in the phase distribution φ(x, y) may be an element for making the magnitudes of all the four-direction in-plane wavenumber vectors K1 to K4 greater than 0, that is, an element for making the in-plane wavenumber vectors K1 to K4 non-zero vectors. For example, such an element allows the light output Lout to be focused into a single focal point U.

The phase distribution φ(x, y) may include, as the element, the phase distribution obtained by synthesizing the hologram phase distribution φ_{H}(x, y) for emitting the light output Lout toward at least two points, and the lens phase distribution φ_{L}(x, y) for focusing the light output Lout. For example, such an element allows the light output Lout to be focused to at least two focal points U.

As shown in part (a) of FIG. 6, the at least two focal points U may be arranged in a direction intersecting the thickness direction, that is, the Z direction. In this case, the light-emitting device 1 can be used, for example, for purposes such as causing light from at least two focal points U to interfere with each other.

As shown in part (b) of FIG. 6, the element of the phase distribution φ(x, y) is an element for focusing the light output Lout to at least four focal points U, and the at least four focal points U may be distributed three-dimensionally. In this case, the light-emitting device 1 can be used, for example, for purposes such as creating a three-dimensional, in other words, stereoscopic optical image.

### Second Embodiment

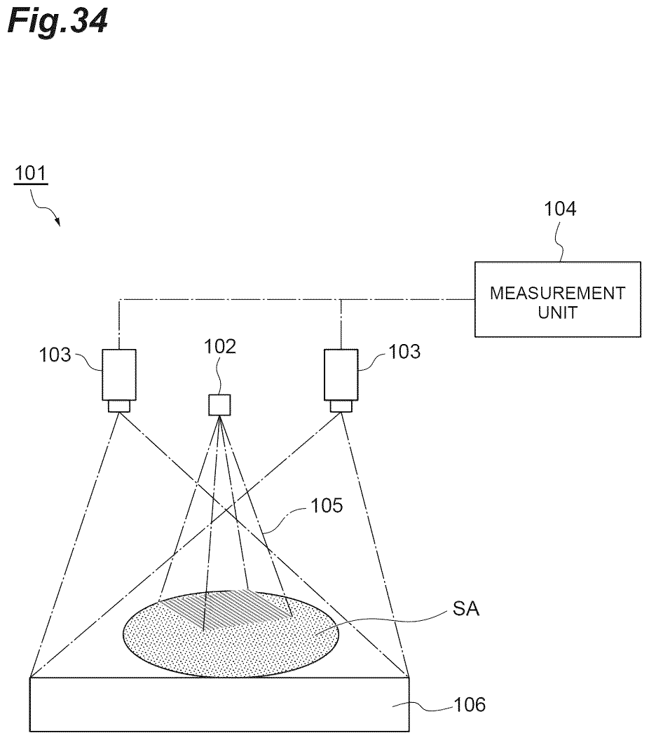

FIG. 34 is a schematic diagram showing the configuration of a three-dimensional measurement system 101 according to a second embodiment. As shown in the figure, the three-dimensional measurement system 101 includes a light source device 102, a plurality of image capturing units 103, and a measurement unit 104. The plurality of image capturing units 103 is, for example, one pair of image capturing units 103. The light source device 102 includes one or more light-emitting devices 1 of the first embodiment. A certain region on a surface of an object to be measured SA placed on a stage 106 is irradiated with measurement light 105 emitted from the light source device 102. The stage 106 may be a scanning stage capable of scanning in a two-dimensional or three-dimensional direction. When the irradiation range of the measurement light 105 is sufficiently wide for the measurement target range of the object to be measured SA, the arrangement of the stage 106 may be omitted.

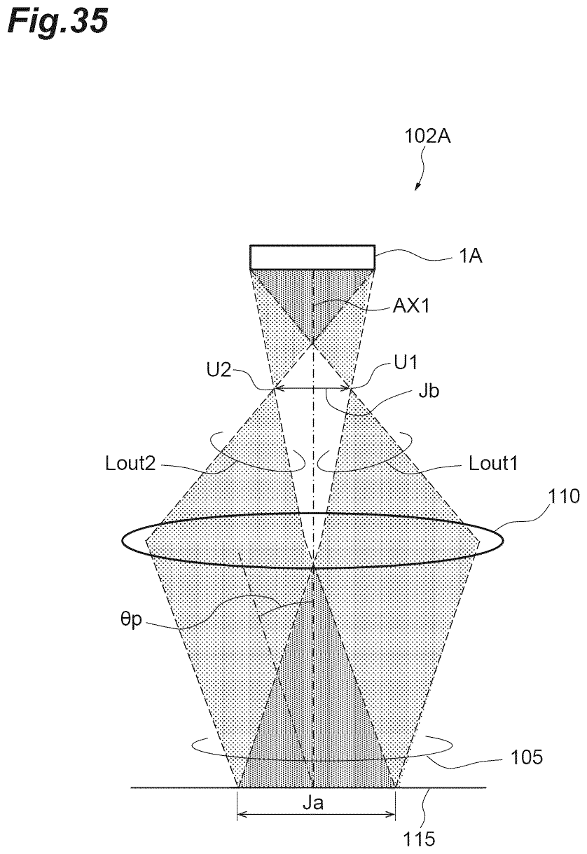

FIG. 35 is a diagram schematically showing a light source device 102A as one example of the configuration of the light source device 102. As shown in the figure, the light source device 102A includes one light-emitting device 1A and an optical system 110. The optical system 110 is optically coupled to a light emission surface of the light-emitting device 1A. In one example, the optical axis of the optical system 110 agrees with an axis AX1. The axis AX1 passes through the center of the light emission surface of the light-emitting device 1A and extends along the Z direction (see FIG. 1). The optical system 110 is a lens having a light focusing action, for example, a convex lens.

The light-emitting device 1A is the light-emitting device 1 of the first embodiment, and forms two focal points U1 and U2 located between the light-emitting device 1 and the optical system 110. That is, an element included in a phase distribution φ(x, y) of a phase modulation layer 15 of the light-emitting device 1A for focusing light output has a multiple focal points type configuration as described in the first embodiment. This element focuses light output Lout1 output from the light-emitting device 1A to the focal point U1, and focuses light output Lout2 output from the light-emitting device 1A to the focal point U2 at the same time. The focal points U1 and U2 are formed side by side in a direction intersecting, for example, perpendicular to the axis AX1. The distance from the axis AX1 to the focal point U1 is equal to the distance from the axis AX1 to the focal point U2. In other words, the focal points U1 and U2 are formed at symmetrical positions with respect to the axis AX1. The light output Lout1 is an example of first light output in the present disclosure. The light output Lout2 is an example of second light output in the present disclosure. The focal point U1 is an example of the first focal point in the present disclosure. The focal point U2 is an example of the second focal point in the present disclosure.

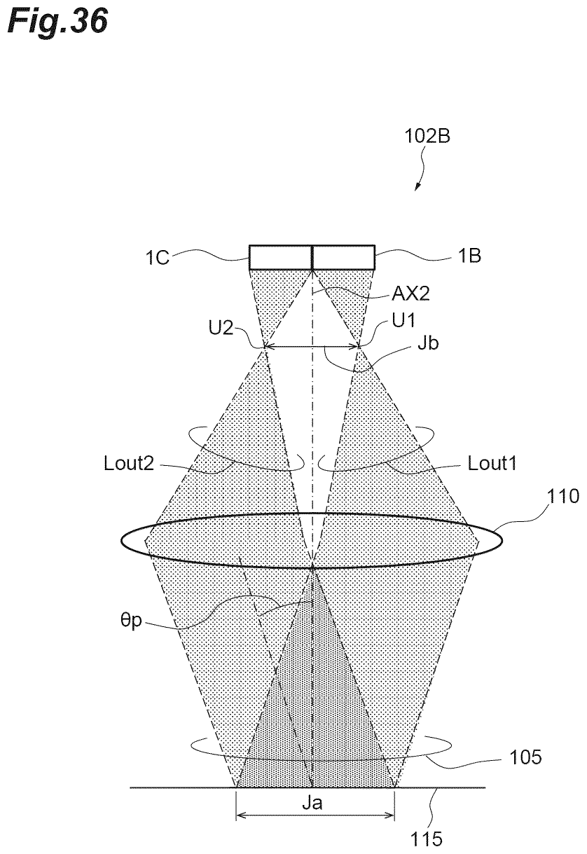

FIG. 36 is a diagram schematically showing a light source device 102B as another example of the configuration of the light source device 102. As shown in the figure, the light source device 102B includes two light-emitting devices 1B and 1C and the optical system 110. Normal lines of the light emission surfaces of the light-emitting devices 1B and 1C are parallel to each other and located in a common plane. The light-emitting device 1B is an example of the first light-emitting device in the present disclosure. The light-emitting device 1C is an example of the second light-emitting device in the present disclosure.

The optical system 110 is provided in common to the two light-emitting devices 1B and 1C, and is optically coupled to the light emission surfaces of the light-emitting devices 1B and 1C. In one example, the optical axis of the optical system 110 agrees with an axis AX2. The axis AX2 passes through the midpoint of the light-emitting devices 1B and 1C, and extends along the Z direction (see FIG. 1). The optical system 110 is a lens having a light focusing action, for example, a convex lens.

The light-emitting devices 1B and 1C are each the light-emitting device 1 of the first embodiment. The element included in the phase distribution φ(x, y) of the phase modulation layer 15 of the light-emitting devices 1B and 1C for focusing light output has a single focal point type configuration as described in the first embodiment. The element of the light-emitting device 1B focuses the light output Lout1 output from the light-emitting device 1B to the focal point U1 located between the light-emitting device 1B and the optical system 110. The element of the light-emitting device 1C focuses the light output Lout2 output from the light-emitting device 1C to the focal point U2 located between the light-emitting device 1C and the optical system 110. Positions where the focal points U1 and U2 are formed are the same as in the example shown in FIG. 35.

In FIGS. 35 and 36, the light output Lout1 passing through the focal point U1 and the light output Lout2 passing through the focal point U2 pass through the optical system 110. The optical system 110 causes the light output Lout1 and Lout2 to form images on an image-forming surface 115, and causes the light output Lout1 and Lout2 to interfere with each other on the image-forming surface 115. The surface of the object to be measured SA is irradiated with interference light generated in this way as the measurement light 105 shown in FIG. 34. Note that a single lens is shown as the optical system 110 in each figure, but the optical system 110 may include a combination of multiple lenses.

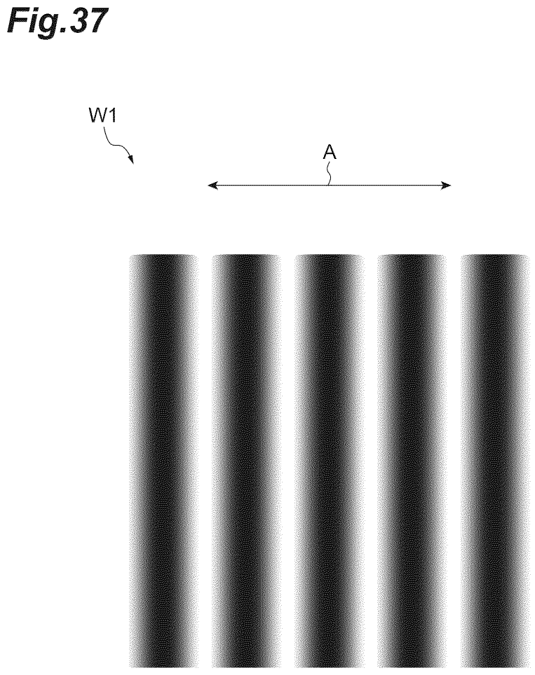

FIG. 37 is a diagram showing an interference optical image on the image-forming surface 115, that is, an intensity change pattern of the measurement light 105. As shown in the figure, the intensity change pattern of the measurement light 105 is a stripe pattern W1 in which light intensity periodically changes along a certain direction A in a sinusoidal manner.

Refer to FIG. 34 again. The image capturing unit 103 includes a device sensitive to the measurement light 105 emitted from the light source device 102. As the image capturing unit 103, for example, a charge coupled device (CCD) camera, a complementary MOS (CMOS) camera, other two-dimensional image sensor, or the like can be used. The image capturing unit 103 captures images of the object to be measured SA irradiated with the measurement light 105 and outputs an output signal indicating image capturing results to the measurement unit 104.

The measurement unit 104 includes, for example, a computer system including a processor, memory, and the like. The measurement unit 104 executes various control functions by means of the processor. Examples of the computer system include a personal computer, a microcomputer, a cloud server, or a smart device such as a smart phone or a tablet terminal. The measurement unit 104 may include a programmable logic controller (PLC), and may include an integrated circuit such as a field-programmable gate array (FPGA).

The measurement unit 104 is communicatively connected to the image capturing units 103. The measurement unit 104 performs three-dimensional shape measurement of the object to be measured SA based on signals input from the image capturing units 103. In the present embodiment, the measurement unit 104 measures the three-dimensional shape of the object to be measured SA based on the phase shift method using the sinusoidal stripe pattern W1. That is, the period T of the sinusoidal wave is equally divided into N, and measurement is performed using a plurality of sinusoidal stripe patterns W1 whose phase is shifted by T/N. N is an integer. In other words, the phase of the plurality of sinusoidal stripe patterns W1 is shifted by 2π/N. Such a phase shift can be implemented, for example, by moving the positions of the focal points U1 and U2 little by little in a direction intersecting the axis AX.

As one example, a case of using four sinusoidal stripe patterns W1 whose phases are shifted by π/2 from each other is shown. It is assumed that the light intensity of the measurement light 105 having the four sinusoidal stripe patterns W1 is I0 to I3, and the coordinates of the pixels of the image capturing unit 103 are (x, y). The light intensity I0 to I3 on the surface of the object to be measured SA is represented by the following Formulas (32) to (35), respectively. Ia(x, y) is the lattice pattern amplitude, Ib(x, y) is the background intensity, and θ(x, y) is the initial phase.

[Formula 32]

I0=Ia(x,y)cos{θ(x,y)}+Ib(x,y) (32)

[Formula 33]

I1=Ia(x,y)cos{θ(x,y)+π/2}+Ib(x,y) (33)

[Formula 34]

I2=Ia(x,y)cos{θ(x,y)+π}+Ib(x,y) (34)

[Formula 35]

I3=Ia(x,y)cos{θ(x,y)+3π/2}+Ib(x,y) (35)

The initial phase θ can be obtained by tan θ=−(I3−I1)/(I2−I0). When the number of phase shifts of the sinusoidal stripe pattern W1 is N, the initial phase θ can be obtained by the following Formula (36).

$$[ Formula 36 ]$$

$$tan θ = - {\sum }_{n = 0}^{N - 1} \frac{In sin ( n \frac{2 π}{N} )}{In cos ( n \frac{2 π}{N} )} \qquad ( 36 )$$

When using such a phase shift method, the measured phase is converted into the height of the object to be measured SA. This makes it possible to measure the height of the object to be measured SA at intervals smaller than the pitch of the sinusoidal stripe pattern W1.

With the light source device 102A or 102B provided in the three-dimensional measurement system 101 of the present embodiment, as described above, an interference fringe is generated by the two light output Lout1 and Lout2 emitted toward the focal points U1 and U2, respectively. This interference fringe is an optical image with a sinusoidal increase and decrease in light intensity along a certain direction, that is, the stripe pattern W1. Such a stripe pattern W1 can be suitably used in the three-dimensional measurement system 101. Furthermore, these light-emitting devices 1A to 1C provided in the light source device 102A or 102B can be significantly miniaturized more than conventional light sources. Therefore, the light source device 102A or 102B can be disposed in a very small space. The light source device 102A or 102B can be inserted into small spaces that have been previously not possible, for example, into the body such as oral cavity and body cavity, inside a tube, gap between walls, or gap between furniture or device and floor, and the like. Therefore, diagnosis with imaging and examination in these small spaces can be facilitated.

As in the present embodiment, the light source device 102A or 102B may include the optical system 110 optically coupled to the light-emitting devices 1A to 1C. The focal points U1 and U2 may be located between the light-emitting devices 1A to 1C and the optical system 110, and the light output Lout1 and Lout2 may interfere with each other after passing through the optical system 110. In this case, the size Ja of the region irradiated with the stripe pattern W1 (see FIGS. 35 and 36) is mainly determined by the focal lengths of the light-emitting devices 1A to 1C, the optical axis location of the optical system 110, and the focal length of the optical system 110. Therefore, regardless of the area of the light emission surface of the light-emitting devices 1A to 1C, it is possible to easily expand the irradiation surface of the stripe pattern W1. In addition, by arbitrarily selecting the interval Jb between the focal point U1 and the focal point U2, the irradiation angle θp, which is the angle between the optical axis of the light output Lout1 and Lout2 and the axis AX1 or AX2, can be easily controlled. Therefore, the interval between stripes of the stripe pattern W1, that is, the period of intensity change can be arbitrarily changed, thereby making it possible to implement an appropriate interval between stripes according to the size of the object to be measured SA.

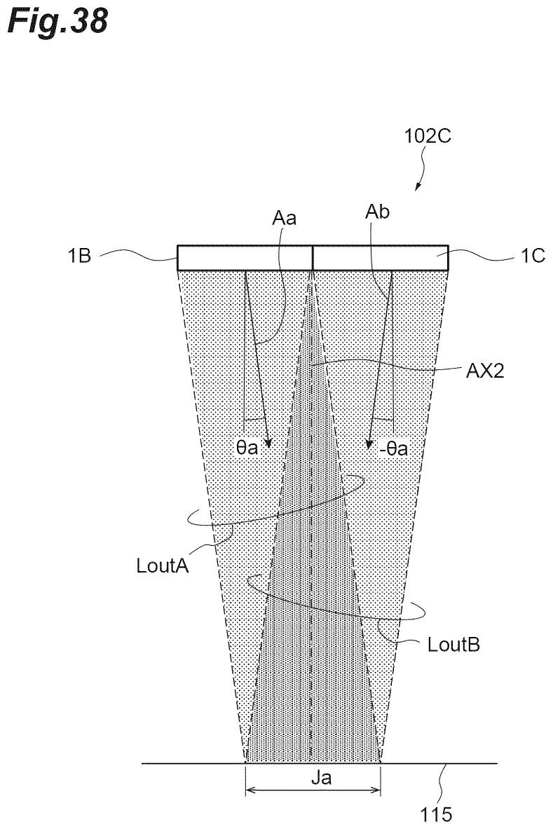

FIG. 38 is a schematic diagram showing the configuration of a light source device 102C according to a comparative example. Unlike the light source device 102B shown in FIG. 36, this light source device 102C does not include the element for focusing light in the phase distribution φ(x, y) of the light-emitting devices 1B and 1C, and emits each of light output LoutA and LoutB as plane waves. In addition, the light source device 102C does not include the optical system 110. The light output LoutA from the light-emitting device 1B is emitted in a direction Aa inclined by an angle θa with respect to the axis AX2. The light output LoutB from the light-emitting device 1C is emitted in a direction Ab inclined by an angle −θa with respect to the axis AX2. The light output LoutA and LoutB interfere with each other to form an interference fringe on the image-forming surface 115, that is, the stripe pattern W1 shown in FIG. 37.

In the light source device 102C, the size Ja of the region irradiated with the stripe pattern W1 is mainly determined by the size of the light emission surface of each of the light-emitting devices 1B and 1C. It is difficult to make the size Ja of the region irradiated with the stripe pattern W1 larger than the light emission surface of each of the light-emitting devices 1B and 1C. Therefore, the size of the object to be measured SA that can be measured is limited.

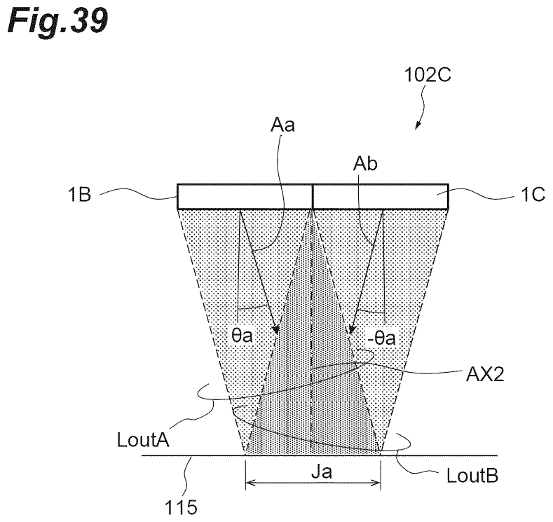

To change the interval between stripes of the stripe pattern W1, that is, the period of intensity change, it is necessary to control the angles θa and −θa of emission directions Aa and Ab of the light output LoutA and LoutB. FIG. 39 schematically shows the state where the angle θa is increased. As is apparent from the comparison between FIGS. 39 and 38, as the angle θa is increased, the irradiation surface of the stripe pattern W1, that is, the image-forming surface 115 approaches the light-emitting devices 1B and 1C. Therefore, to change the interval between stripes of the stripe pattern W1, it is necessary to change the arrangement of the light-emitting devices 1B and 1C as well, and there is a problem that the degree of freedom of controlling the interval between stripes is low. In contrast, in the light source device 102B of the present embodiment, to change the interval between stripes of the stripe pattern W1, it is sufficient to change the interval between the focal points U1 and U2 and the focal length of the optical system 110, and there is no need to change the arrangement of the light-emitting devices 1B and 1C. Therefore, it is possible to easily change the interval between stripes of the stripe pattern W1.

As described above, the light source device 102 of the present embodiment emits the light output Lout1 and Lout2 while focusing the light by applying an ingenious way to the phase distribution φ(x, y) of the S-iPM laser, and causes the light output to interfere with each other. Mutual interference of two light can be implemented not only by the S-iPM laser, but also, for example, by spatially modulating the phase of light by using a phase modulation type spatial light modulator (SLM). However, the technical concept differs greatly between the method using the SLM and the method of the present embodiment using the iPM laser.

The SLM originally outputs modulated light in a direction intersecting the light modulation surface. In the S-iPM laser, the signal light such as the +1-order light and the −1-order light corresponds to the modulated light of SLM, and in order to output only the signal light in the direction intersecting the light emission surface, it is required to apply an ingenious way. A Γ-point oscillation S-iPM laser is being studied, and the Γ-point oscillation S-iPM laser emits zero-order light in a direction perpendicular to the light emission surface. Since the zero-order light is not affected by the phase distribution φ(x, y), the zero-order light becomes unnecessary light, that is, noise when emitting light while focusing the light as in the present embodiment. When the S-iPM laser performs M-point oscillation, it is possible to suppress the zero-order light from being emitted in a direction perpendicular to the light emission surface. However, if the S-iPM laser simply performs M-point oscillation, the signal light such as the +1-order light and the −1-order light will also not be emitted in the direction intersecting the light emission surface. For such an issue, in the present embodiment, the diffraction vector V1 is added to the in-plane wavenumber vectors K1 to K4, and the magnitude of at least one of the in-plane wavenumber vectors K1 to K4 is made smaller than 2π/λ, that is, the light line LL. This enables the signal light to be emitted in a direction intersecting the light emission surface. Such an ingenious way cannot be easily conceived from the method using the SLM.

In the S-iPM laser, the formation of a two-dimensional hologram in the plane perpendicular to the light emission direction, that is, the Z direction, has been demonstrated. The light-emitting device 1 of the present embodiment can also enable a three-dimensional hologram by differentiating the positions of the plurality of focal points in the Z direction. The formation of the three-dimensional hologram using the S-iPM laser has not been demonstrated so far.

A lens action is given to the phase pattern of the SLM to focus the modulated light. However, the SLM implements the lens action simply by modulating the phase of light on a pixel-by-pixel basis. In contrast, since the S-iPM laser modulates the phase of the plane wave in the resonant state while propagating inside the phase modulation layer 15, it has been unclear whether the light focusing action can be implemented. The present inventor has actually produced such an S-iPM laser and conducted the experiment, thereby making it clear that the light focusing action can be implemented.

(First Modification)

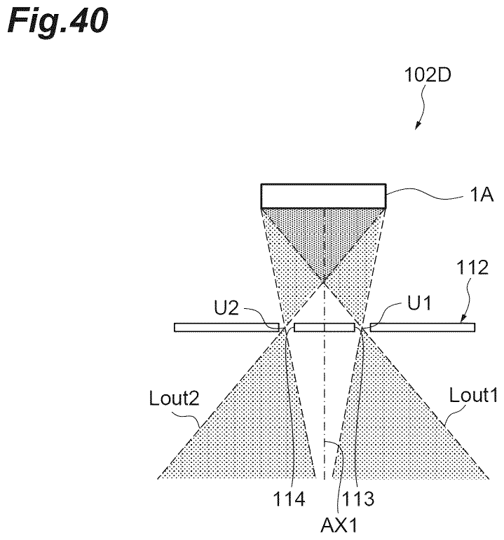

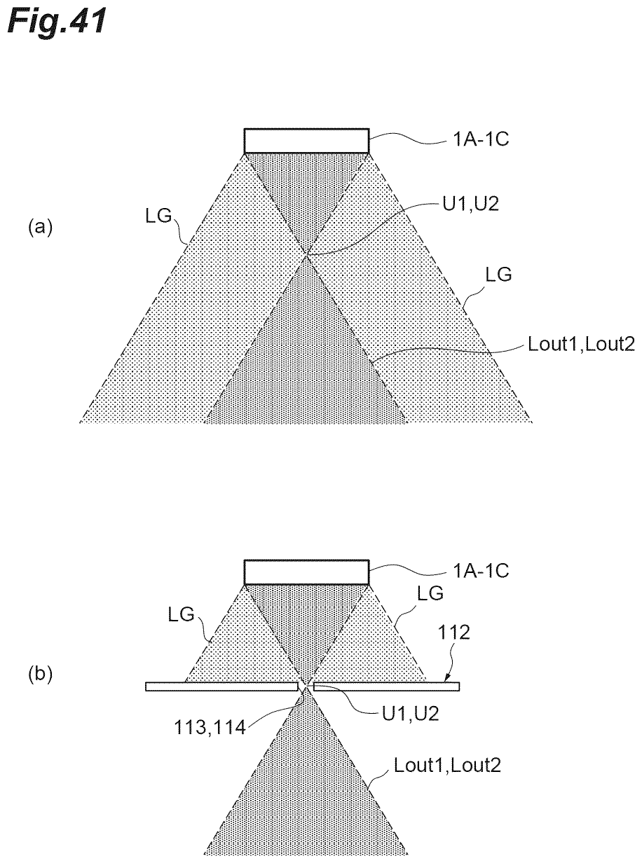

FIG. 40 is a schematic diagram partially showing the configuration of a light source device 102D according to a first modification. The light source device 102D further includes a mask 112 for a mode filter in addition to the configuration of the light source device 102A of the second embodiment shown in FIG. 35. The mask 112 includes two optical openings 113 and 114 for passing light output Lout1 and Lout2, respectively. The position of the optical opening 113 in the direction along the axis AX1, that is, in the Z direction overlaps with the focal point U1. The position of the optical opening 114 in the same direction overlaps with the focal point U2. The inner diameter of the optical opening 113 is larger than the light diameter of the light output Lout1 at the focal point U1, that is, the beam waist diameter. The inner diameter of the optical opening 114 is larger than the light diameter of the light output Lout2 at the focal point U2, that is, the beam waist diameter. The configuration of the light source device 102D except the mask 112 is the same as the configuration of the light source device 102A of the second embodiment. The light source device 102B of the second embodiment may further include the mask 112, in a similar manner to the present modification.

FIG. 41 is a diagram for describing effects of providing the mask 112. When the light-emitting device 1A emits the light output Lout1 and Lout2, ghost light LG due to the −1-order light and/or the back surface reflection is emitted while diffusing from the light-emitting device 1A at the same time as the light output Lout1 and Lout2. Similarly, when the light-emitting device 1B emits the light output Lout1 and the light-emitting device 1C emits the light output Lout2, the ghost light LG due to the −1-order light and/or the back surface reflection is emitted while diffusing from the light-emitting devices 1B and 1C at the same time as the light output Lout1 and Lout2. The ghost light LG is, for example, light with a different sign of diffraction order from the light output Lout1 and Lout2, and is, for example, the −1-order light. When the mask 112 is not provided as shown in part (a) of FIG. 41, the ghost light LG overlaps with the light output Lout1 and Lout2, causing the spatial mode of the light output Lout1 and Lout2 to be disturbed. In contrast, when the mask 112 is provided as shown in part (b) of FIG. 41, only the light output Lout1 and Lout2 passes through the optical openings 113 and 114, respectively, and the ghost light LG is blocked by the mask 112. Therefore, the ghost light LG can be removed from the light output Lout1 and Lout2. In this way, the present modification can easily perform mode cleaning of the light output Lout1 and Lout2.

### Third Embodiment

Subsequently, the third embodiment will be described. In each of the embodiments described above, the case of focusing light to a point shape has been described. The present embodiment will describe the case of focusing light in only one direction.

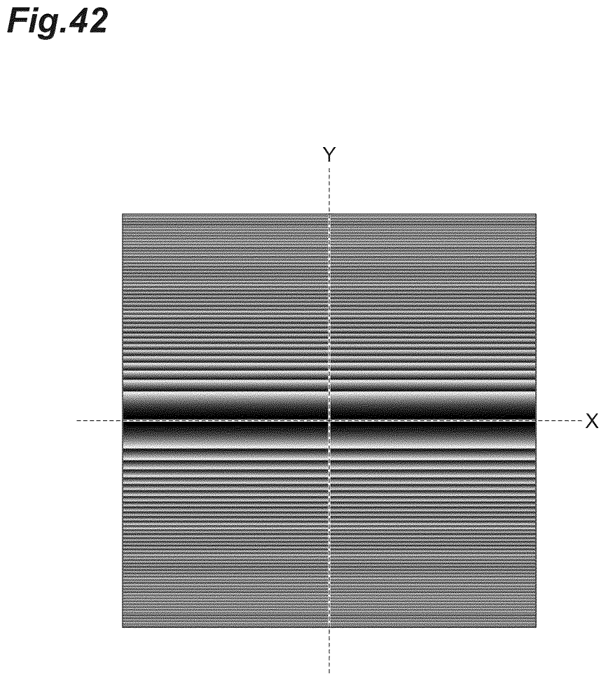

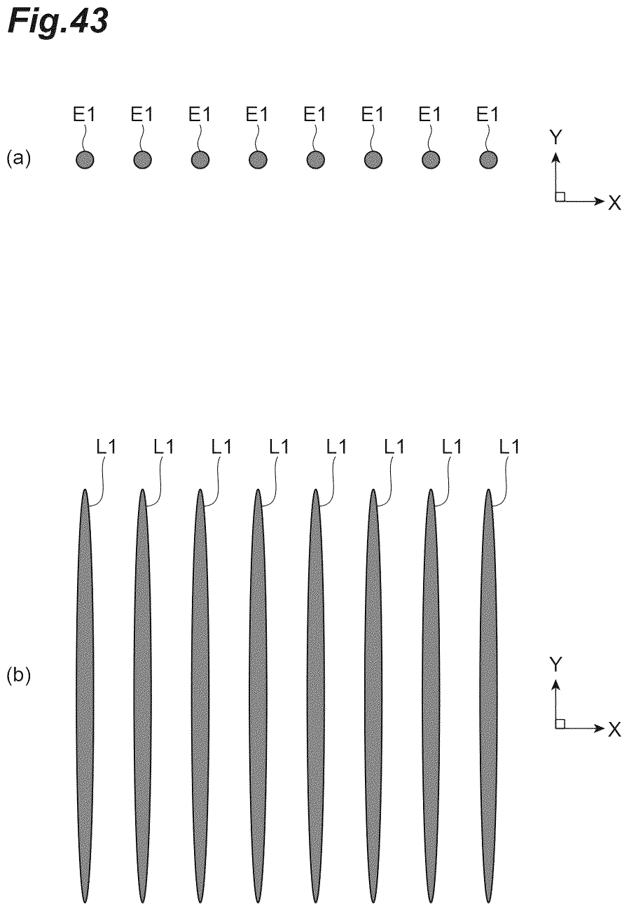

FIG. 42 is a diagram showing an example of a lens phase distribution φ_{L}(x, y) for focusing light only in one direction. In this figure, the magnitude of the phase is represented by a shade of color. The magnitude of the phase is closer to 0 (rad) as the color is darker, and is closer to 2π (rad) as the color is lighter. In this example, the phase increases with distance in the Y direction from the position of Y=0, and the phase is constant in the X direction. The X direction is the first direction in the present embodiment, and the Y direction is the second direction in the present embodiment. This lens phase distribution φ_{L}(x, y) can act as a one-dimensional concave lens element for the light output in the Y direction only. The lens phase distribution φ_{L}(x, y) as the one-dimensional lens element is represented by Formula (37). Here, λ is the wavelength in the medium in the phase modulation layer 15, (x, y) is the in-plane lattice point position, and f is the focal length. When the sign on the right side is positive, the lens phase distribution φ_{L}(x, y) is a one-dimensional concave lens element, and the −1-order light is focused in the region of z>0. When the sign on the right side is negative, the lens phase distribution φ_{L}(x, y) is a one-dimensional convex lens element, and the +1-order light is focused in the region of z>0. The focal length f is, for example, 100 μm.

$$[ Formula 37 ]$$

$${ϕ}_{L} ( x , y ) = \pm \frac{2 π}{λ} ( \sqrt{{y}^{2} + {f}^{2}} - f ) \qquad ( 37 )$$

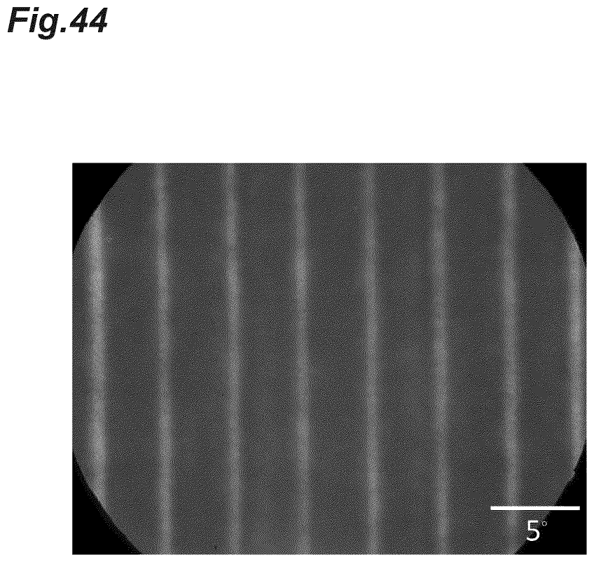

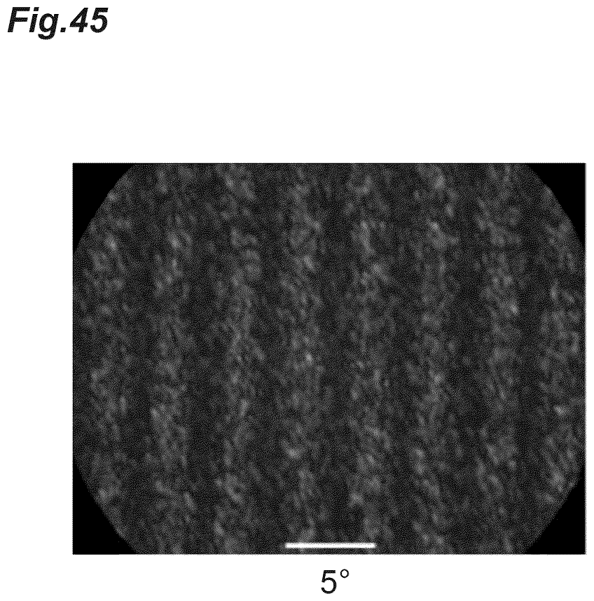

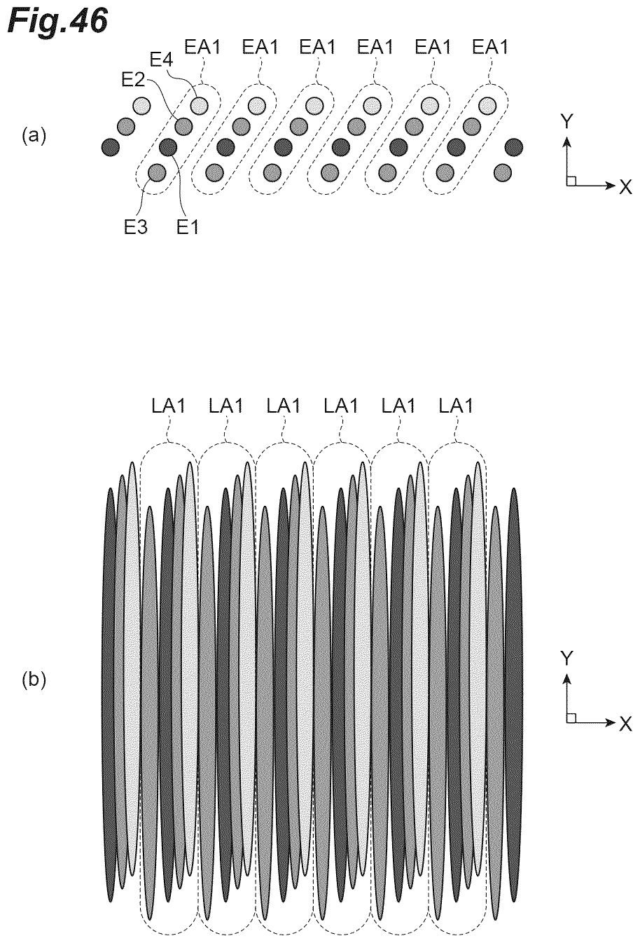

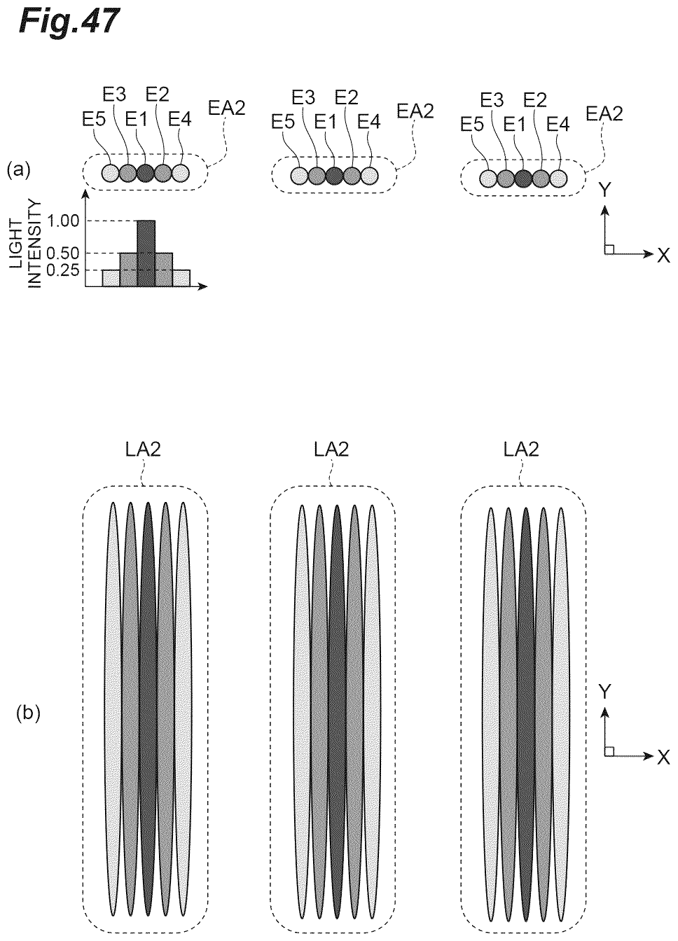

FIG. 43 is a diagram conceptually showing an operation for forming a striped optical image. Part (a) of FIG. 43 is a diagram schematically showing an example of an optical image formed on one imaginary plane only by a hologram phase distribution φ_{H}(x, y). This optical image includes a plurality of bright spots E1 arranged in a row and at equal intervals on the X axis. Part (b) of FIG. 43 is a diagram schematically showing an optical image obtained by superimposing the lens phase distribution φ_{L}(x, y) shown in FIG. 42 on the hologram phase distribution φ_{H}(x, y) forming the optical image shown in part (a) of FIG. 43. The plurality of bright spots E1 formed by the hologram phase distribution φ_{H}(x, y) is extended in the Y direction by the lens phase distribution φ_{L}(x, y) to form a plurality of bright lines L1, as shown in part (b) of FIG. 43. This is the result of each bright spot E1 once focused in the Y direction and then expanded in the same direction. In this way, by superimposing the lens phase distribution φ_{L}(x, y) as a one-dimensional lens element focusing light in the direction orthogonal to the arrangement direction on the hologram phase distribution φ_{H}(x, y) forming the plurality of bright spots E1 arranged in a row and at equal intervals on the X axis, the striped optical image can be obtained. The striped optical image can be suitably used, for example, in the three-dimensional measurement system of the second embodiment. The present inventor prototyped such a light-emitting device. FIG. 44 is a far-field image of the striped optical image emitted from the prototype light-emitting device. FIG. 45 shows a far-field image when the striped optical image is formed only by the hologram phase distribution φ_{H}(x, y) without using the lens phase distribution φ_{L}(x, y) for comparison. A comparison with FIG. 45 shows that in the far-field image shown in FIG. 44, noise included in the optical image, that is, uneven luminance is significantly reduced, and that a clear striped pattern is obtained. Such a clear striped optical image contributes to the improvement of measurement precision in the three-dimensional measurement system. In addition, the light can be focused to an extremely short focal length of 100 μm, for example, compared to a case where a lens component such as a cylindrical lens is separately provided. Therefore, the striped pattern can be extended longer.

FIG. 46 is a diagram conceptually showing an operation for forming a striped optical image different from the one described above. The aspect shown in FIG. 46 differs from the aspect shown in FIG. 43 in the shape of the optical image formed by the hologram phase distribution φ_{H}(x, y). That is, the optical image shown in part (a) of FIG. 46 includes a plurality of bright spot groups EA1 arranged in a row and at equal intervals on the X axis. Each bright spot group EA1 includes four bright spots E1, E2, E3, and E4. The light intensity of the bright spot E2 and the light intensity of the bright spot E3 are smaller than the light intensity of the bright spot E1 and equal to each other. The light intensity of the bright spot E4 is smaller than the light intensity of the bright spots E2 and E3. In FIG. 46, the light intensity of each bright spot is represented by a shade of color. The light intensity increases as the color becomes darker, and the light intensity decreases as the color becomes lighter. The bright spots E2 and E3 are arranged on both sides of the bright spot E1 in the X direction. The bright spot E4 is arranged in the X direction between the bright spot E2 of the bright spot group EA1 to which the bright spot E4 belongs and the bright spot E3 of the bright spot group EA1 adjacent to the bright spot group EA1. Alternatively, the bright spot E4 may be arranged in the X direction between the bright spot E3 of the bright spot group EA1 to which the bright spot E4 belongs and the bright spot E2 of the bright spot group EA1 adjacent to the bright spot group EA1. In the example shown in part (a) of FIG. 46, the bright spots E1 to E4 are shifted from each other in the Y direction, but positions of some or all of the bright spots in the Y direction may agree with each other.

Part (b) of FIG. 46 is a diagram schematically showing an optical image obtained by superimposing the lens phase distribution φ_{L}(x, y) shown in FIG. 42 on the hologram phase distribution φ_{H}(x, y) forming the optical image shown in part (a) of FIG. 46. The plurality of bright spot groups EA1 formed by the hologram phase distribution φ_{H}(x, y) is extended in the Y direction by the lens phase distribution φ_{L}(x, y) to form a plurality of bright line groups LA1, as shown in part (b) of FIG. 46. This is the result of each bright spot group EA1 once focused in the Y direction and then expanded in the same direction. A substantially sinusoidal intensity distribution is obtained in the X direction due to the difference in the light intensity of each bright line included in the bright line group LA1. The striped optical image obtained in this way can also be suitably used in the three-dimensional measurement system of the second embodiment.

FIG. 47 is a diagram showing the aspect similar to the aspect shown in FIG. 46. The aspect shown in FIG. 47 differs from the aspect shown in FIG. 46 in the shape of the optical image formed by the hologram phase distribution φ_{H}(x, y). That is, the optical image shown in part (a) of FIG. 47 includes a plurality of bright spot groups EA2 arranged in a row and at equal intervals on the X axis. The plurality of bright spot groups EA2 is arranged apart from each other in the X direction. Each bright spot group EA2 includes five bright spots E1, E2, E3, E4, and E5. The light intensity of the bright spot E2 and the light intensity of the bright spot E3 are smaller than the light intensity of the bright spot E1 and equal to each other. The light intensity of the bright spots E4 and E5 is smaller than the light intensity of the bright spots E2 and E3 and equal to each other. The bright spots E2 and E3 are arranged on both sides of the bright spot E1 in the X direction. The bright spots E4 and E5 are arranged on both sides of the bright spots E1 to E3 in the X direction. In the example shown in part (a) of FIG. 47, positions of the bright spots E1 to E5 agree with each other in the Y direction, but some or all of the bright spots may be shifted from each other in the Y direction. Part (a) of FIG. 47 shows, as one example, an example of relative values of the light intensity of the bright spots E1 to E5 in a graph. In this example, when the light intensity of the bright spot E1 is 1.0, the light intensity of the bright spots E2 and E3 is 0.50, and the light intensity of the bright spots E4 and E5 is 0.25.

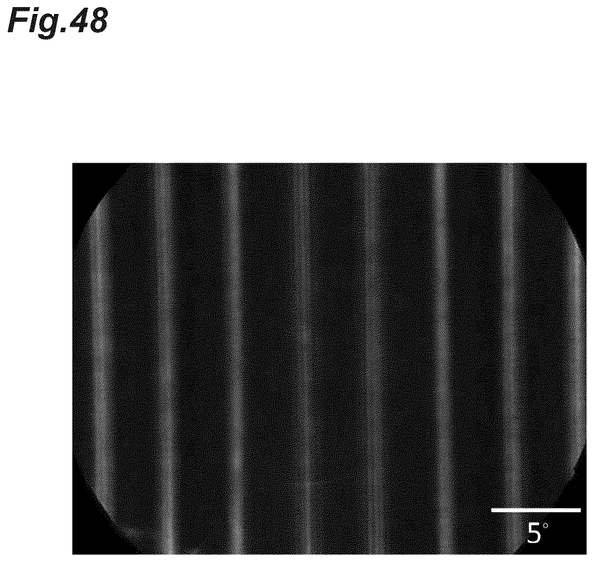

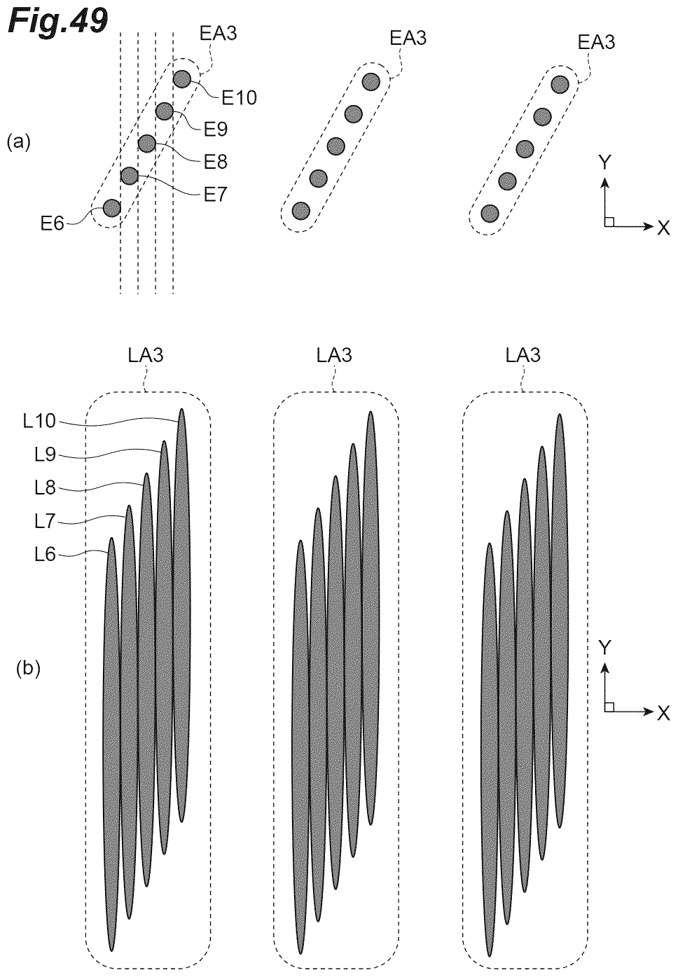

Part (b) of FIG. 47 is a diagram schematically showing an optical image obtained by superimposing the lens phase distribution φ_{L}(x, y) shown in FIG. 42 on the hologram phase distribution φ_{H}(x, y) forming the optical image shown in part (a) of FIG. 47. The plurality of bright spot groups EA2 formed by the hologram phase distribution φ_{H}(x, y) is extended in the Y direction by the lens phase distribution φ_{L}(x, y) to form a plurality of bright line groups LA2, as shown in part (b) of FIG. 47. This is the result of each bright spot group EA2 once focused in the Y direction and then expanded in the same direction. Because of the difference in the light intensity of each bright line included in the bright line group LA2, an intensity distribution is obtained in which the light intensity increases and decreases in a substantially sinusoidal manner along the X direction. The striped optical image obtained in this way can also be suitably used in the three-dimensional measurement system of the second embodiment. The present inventor prototyped such a light-emitting device. FIG. 48 is a far-field image of the striped optical image emitted from the prototype light-emitting device. A comparison with FIG. 45 shows that in the far-field image shown in FIG. 48 as well, noise included in the optical image, that is, uneven luminance is significantly reduced, and that a clear striped pattern is obtained.

FIG. 49 is a diagram showing another aspect similar to the aspect shown in FIG. 46. The aspect shown in FIG. 49 differs from the aspect shown in FIG. 46 in the shape of the optical image formed by the hologram phase distribution φ_{H}(x, y). That is, the optical image shown in part (a) of FIG. 49 includes a plurality of bright spot groups EA3 arranged in a row and at equal intervals on the X axis. The plurality of bright spot groups EA3 is arranged apart from each other in the X direction. Each bright spot group EA3 includes five bright spots E6, E7, E8, E9, and E10. In the illustrated example, the light intensity of each of the bright spots E6 to E10 is equal to each other, but for example, as in the aspect shown in part (a) of FIG. 47, the light intensity of the bright spots E7 and E9 may be smaller than the light intensity of the bright spot E8, and the light intensity of the bright spots E6 and E10 may be smaller than the light intensity of the bright spots E7 and E9. The bright spots E6 to E10 are arranged side by side in this order in the X direction, and when projected onto the X axis, the bright spots E6 to E10 are continuous without any gap. In the example shown in part (a) of FIG. 49, the bright spots E6 to E10 are shifted from each other in the Y direction, but positions of some or all of the bright spots in the Y direction may agree with each other.

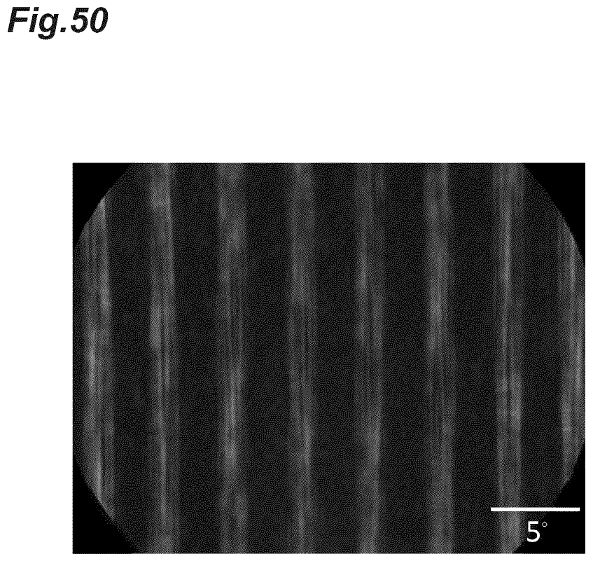

Part (b) of FIG. 49 is a diagram schematically showing an optical image obtained by superimposing the lens phase distribution φ_{L}(x, y) shown in FIG. 42 on the hologram phase distribution φ_{H}(x, y) forming the optical image shown in part (a) of FIG. 49. The plurality of bright spot groups EA3 formed by the hologram phase distribution φ_{H}(x, y) is extended in the Y direction by the lens phase distribution φ_{L}(x, y) to form a plurality of bright line groups LA3, as shown in part (b) of FIG. 49. This is the result of each bright spot group EA3 once focused in the Y direction and then expanded in the same direction. In the bright line group LA3 after being stretched as well, respective bright lines L6 to L10 are adjacent to each other in the X direction. The present inventor prototyped such a light-emitting device. FIG. 50 is a far-field image of the striped optical image emitted from the prototype light-emitting device. A comparison with FIG. 45 shows that in the far-field image shown in FIG. 50 as well, noise included in the optical image, that is, uneven luminance is significantly reduced, and that striped patterns are being clarified.

(Second Modification)

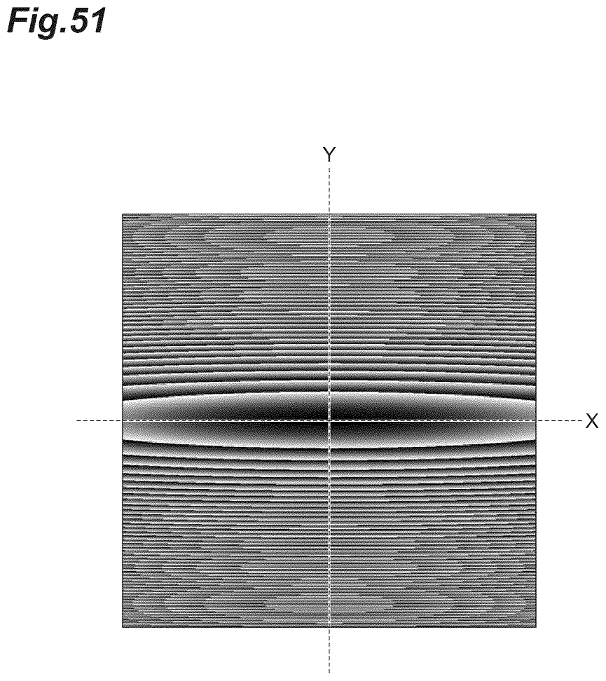

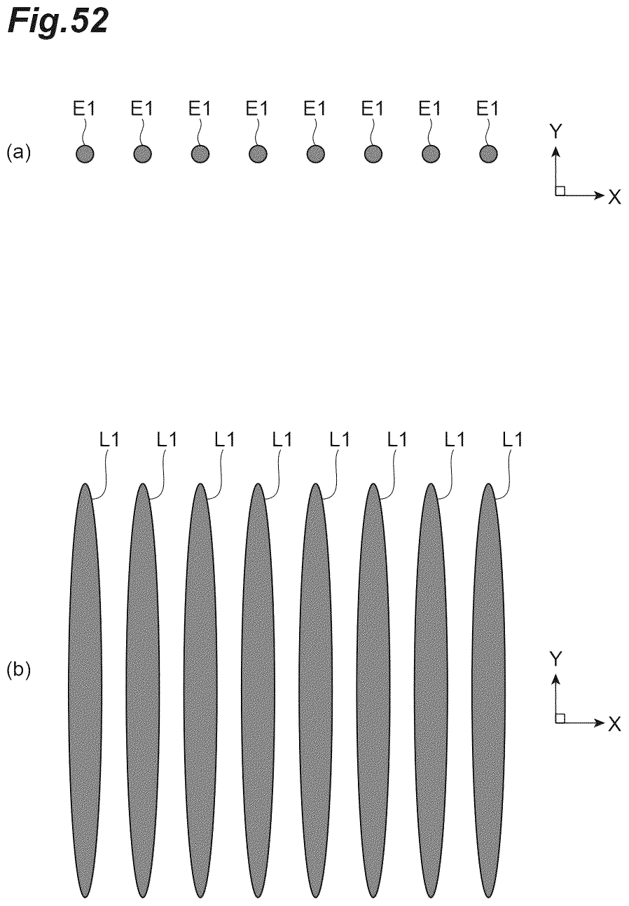

Here, as a modification of the third embodiment, it is considered to give a slight light focusing action not only in the Y direction but also in the X direction. That is, the lens phase distribution φ_{L}(x, y) is set in which the focal length in the X direction is longer than the focal length in the Y direction. FIG. 51 is a diagram showing an example of such a lens phase distribution φ_{L}(x, y). In this figure, the magnitude of the phase is represented by a shade of color. The magnitude of the phase is closer to 0 (rad) as the color is darker, and is closer to 2π (rad) as the color is lighter. This lens phase distribution φ_{L}(x, y) can act as an asymmetric concave lens element for the light output. The lens phase distribution φ_{L}(x, y) as an asymmetric lens element is represented by Formula (38). Here, λ is the wavelength in the medium in the phase modulation layer 15, (x,y) is the lattice point position in the plane, fₓ is the focal length in the X direction, and f_{y} is the focal length in the Y direction. When the sign on the right side is positive, the lens phase distribution φ_{L}(x, y) is an asymmetric concave lens element, and the +1-order light is focused in the region of z>0. When the sign on the right side is negative, the lens phase distribution φ_{L}(x, y) is an asymmetric convex lens element, and the −1-order light is focused in the region of z>0. The focal length fₓ in the X direction is, for example, 10 mm. The focal length f_{y} in the Y direction is, for example, 100 μm.

$$[ Formula 38 ]$$

$${ϕ}_{Lx} ( x ) = \pm \frac{2 π}{λ} ( \sqrt{{y}^{2} + {f}_{x}^{2}} - {f}_{x} ) \qquad ( 38 )$$

$${ϕ}_{Ly} ( y ) = \pm \frac{2 π}{λ} ( \sqrt{{y}^{2} + {f}_{y}^{2}} - {f}_{y} )$$

$${ϕ}_{L} ( x , y ) = {ϕ}_{Lx} ( x ) + {ϕ}_{Ly} ( y )$$

FIG. 52 is a diagram conceptually showing an operation for forming a striped optical image. Part (a) of FIG. 52 is a diagram schematically showing an example of an optical image formed only by the hologram phase distribution φ_{H}(x, y), and showing an optical image as in part (a) of FIG. 43. Part (b) of FIG. 52 is a diagram schematically showing an optical image obtained by superimposing the lens phase distribution φ_{L}(x, y) shown in FIG. 51 on the hologram phase distribution φ_{H}(x, y) forming the optical image shown in part (a) of FIG. 52. In the present modification as well, the plurality of bright lines L1 is stretched in the Y direction by the lens phase distribution φ_{L}(x, y), as shown in part (b) of FIG. 52. At the same time, the plurality of bright lines L1 is also slightly stretched in the X direction by the lens phase distribution φ_{L}(x, y). In this case as well, a striped optical image can be obtained. Such a striped optical image can also be suitably used, for example, in the three-dimensional measurement system of the second embodiment.

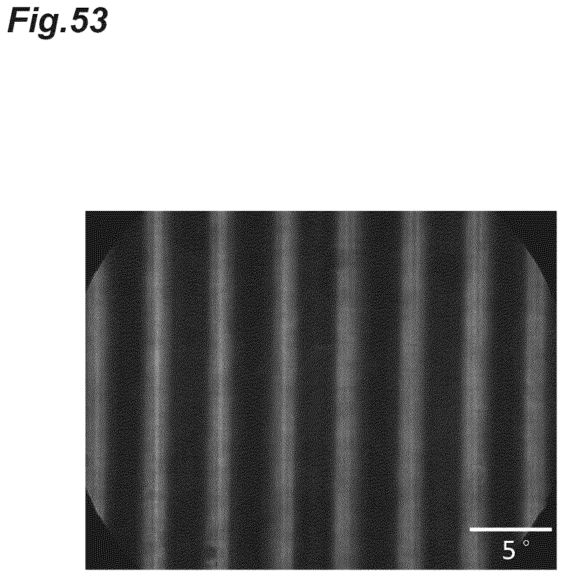

The present inventor has prototyped the light-emitting device of the present modification. FIG. 53 is a far-field image of the striped optical image emitted from the prototype light-emitting device. For comparison, FIG. 44 shows a far-field image of the prototype light-emitting device when the one-dimensional lens phase distribution φ_{L}(x, y) shown in FIG. 42 is used, instead of the asymmetric lens phase distribution φ_{L}(x, y). Comparing FIG. 53 with FIG. 44, the asymmetric lens phase distribution φ_{L}(x, y) according to the present modification allows the width of the stripe to be adjusted widely and can be used to adjust the suitable width required for the three-dimensional measurement system.

The light-emitting device and the light source device according to the present disclosure are not limited to the embodiments described above, and various modifications are possible. The above-described embodiments have exemplified laser devices including GaAs-based, InP-based, and nitride-based (especially GaN-based) compound semiconductors. The present disclosure can apply to laser elements including various semiconductor materials other than these materials. The above-described embodiments have described examples in which the active layer provided on the semiconductor substrate common to the phase modulation layer is set as the light emission portion. In the present disclosure, the light emission portion may be provided separately from the semiconductor substrate. When the light emission portion is optically coupled to the phase modulation layer to provide light to the phase modulation layer, such a configuration also can suitably achieve the same effects as those of the above-described embodiments.

### INDUSTRIAL APPLICABILITY

The embodiments can be used as a light-emitting device capable of miniaturizing a light source device that outputs light while focusing the light, and a light source device including the light-emitting device.

### REFERENCE SIGNS LIST

1, 1A to 1C: light-emitting device, 10: semiconductor substrate, 10a: main surface, 10b: back surface, 11: cladding layer, 12: active layer, 13: cladding layer, 14: contact layer, 15: phase modulation layer, 15a: base region, 15b: modified refractive index region, 16, 17: electrode, 17a: opening, 18: protective film, 19: anti-reflective film, 50A, 50B: random pattern, 51: region, 52: selected region, 53: non-selected region, 100: S-iPM laser, 101: three-dimensional measurement system, 102, 102A to 102D: light source device, 103: image capturing unit, 104: measurement unit, 105: measurement light, 106: stage, 110: optical system, 112: mask, 113, 114: optical opening, 115: image-forming surface, A: direction, Aa, Ab: emission direction, AX, AX1, AX2: axis, B1: basic reciprocal lattice vector, D: straight line, E1 to E10: bright spot, EA1 to EA3: bright spot group, FR: image region, G: center of gravity, K1 to K4, Ka, Kb: in-plane wavenumber vector, L1, L6 to L10: bright line, LA1 to LA3: bright line group, La: +1-order light, Lb: −1-order light, LG: ghost light, LL: light line, LL2: region, LM: optical image, Lout, Lout, Lout, LoutA, LoutB: light output, O: lattice point, PM: projection plane, R: unit constituent region, RIN: inner region, ROUT: outer region, SA: object to be measured, U, U1, U2, UD: focal point, V1: diffraction vector, W1: stripe pattern, θa: angle, θp: irradiation angle.

1. A light-emitting device comprising:
a light emission portion; and
a phase modulation layer optically coupled to the light emission portion and including a base region and a plurality of modified refractive index regions, the plurality of modified refractive index regions having a refractive index different from a refractive index of the base region and distributed in a two-dimensional form in a plane perpendicular to a thickness direction,
wherein a center of gravity of each of the modified refractive index regions is arranged as to have an individual relationship with a corresponding lattice point of a virtual lattice set in the plane according to a predetermined phase distribution, and
the predetermined phase distribution includes an element for focusing light output from the light-emitting device in at least one direction.

2. The light-emitting device according to claim 1, wherein the element of the predetermined phase distribution is an element for focusing the light output to at least two focal points.

3. The light-emitting device according to claim 2, wherein the predetermined phase distribution includes, as the element, a phase distribution obtained by synthesizing a first phase distribution for emitting the light output toward at least two points and a second phase distribution for focusing the light output.

4. The light-emitting device according to claim 2, wherein the at least two focal points are arranged in a direction intersecting the thickness direction.

5. The light-emitting device according to claim 2, wherein
the element of the predetermined phase distribution is an element for focusing the light output to at least four focal points, and
the at least four focal points are distributed three-dimensionally.

6. The light-emitting device according to claim 1, wherein the predetermined phase distribution is obtained by superimposing a hologram phase distribution forming a plurality of bright spots arranged in a first direction and a lens phase distribution having a light focusing action only in a second direction intersecting the first direction.

7. The light-emitting device according to claim 1, wherein
the predetermined phase distribution is obtained by superimposing a hologram phase distribution forming a plurality of bright spot groups arranged in a first direction and a lens phase distribution having a light focusing action only in a second direction intersecting the first direction, and
each of the bright spot groups includes a plurality of bright spots, and light intensities of at least two of the plurality of bright spots differ from each other.

8. The light-emitting device according to claim 7, wherein
each of the bright spot groups includes a first bright spot, a second bright spot, and a third bright spot different in position from each other in the first direction,
the second bright spot and the third bright spot are arranged at positions sandwiching the first bright spot, and
light intensities of the second bright spot and the third bright spot is less than a light intensity of the first bright spot.

9. The light-emitting device according to claim 1, wherein the predetermined phase distribution is obtained by superimposing a hologram phase distribution forming a plurality of bright spots arranged in a first direction and a lens phase distribution having a light focusing action in the first direction and a second direction intersecting the first direction, and having a focal length in the first direction longer than a focal length in the second direction.

10. A light source device comprising:
a first light-emitting device serving as the light-emitting device according to claim 1; and
a second light-emitting device serving as the light-emitting device according to claim 1,
wherein the element of the predetermined phase distribution of the first light-emitting device focuses first light output from the first light-emitting device toward a first focal point,
the element of the predetermined phase distribution of the second light-emitting device focuses second light output from the second light-emitting device toward a second focal point aligned with the first focal point, and
the first light output and the second light output interfere with each other to generate an interference fringe.

11. The light source device according to claim 10, further comprising:
an optical system optically coupled to the first light-emitting device and the second light-emitting device,
wherein the first focal point is located between the first light-emitting device and the optical system,
the second focal point is located between the second light-emitting device and the optical system, and
the first light output and the second light output interfere with each other after passing through the optical system.

12. A light source device comprising:
the light-emitting device according to claim 2,
wherein the element of the predetermined phase distribution of the light-emitting device focuses first light output from the light-emitting device toward a first focal point and focuses second light output from the light-emitting device toward a second focal point, and
the first light output and the second light output interfere with each other to generate an interference fringe.

13. The light source device according to claim 12, further comprising:
an optical system optically coupled to the light-emitting device,
wherein the first focal point and the second focal point are located between the light-emitting device and the optical system, and
the first light output and the second light output interfere with each other after passing through the optical system.

14. The light-emitting device according to claim 1, wherein
the center of gravity of each of the modified refractive index regions has a first arrangement form or a second arrangement form,
in the first arrangement form, the center of gravity of each of the modified refractive index regions is arranged apart from the corresponding lattice point of the virtual lattice set in the plane and has an individual rotation angle according to the predetermined phase distribution around the lattice point, and the rotation angle of the center of gravity of at least two of the modified refractive index regions is different from each other, and
in the second arrangement form, the center of gravity of each of the modified refractive index regions is arranged on a straight line passing through the lattice point of the lattice and inclined with respect to the lattice, an inclination angle of the straight line corresponding to each of the plurality of modified refractive index regions with respect to the lattice is uniform within the phase modulation layer, a distance between the center of gravity of each of the modified refractive index regions and the lattice point corresponding to each of the modified refractive index regions is individually set according to the predetermined phase distribution, and distances between centers of gravity of at least two of the modified refractive index regions and the lattice point are different from each other.

15. The light-emitting device according to claim 1, wherein
a lattice spacing of the lattice and a light emission wavelength λ of the light emission portion satisfy a condition for M-point oscillation, and
four-direction in-plane wavenumber vectors each including a wavenumber spread corresponding to an angular spread of the light output are formed on a reciprocal lattice space of the phase modulation layer, and magnitude of at least one of the in-plane wavenumber vectors is less than 2π/λ.
